(19) United States
(12) Patent Application Publication
(10) Pub. No.: US 2026/0262277 A1
(43) Pub. Date: Sep. 3, 2026

(54) CFET WITH SHORT INNER GATE LENGTH, THIN CHANNEL HEIGHT, AND DUAL CHANNEL ORIENTATION FOR EXTENDING TECHNOLOGY NODE

(71) Applicant: Taiwan Semiconductor Manufacturing Co., Ltd., Hsinchu (TW)

(72) Inventors: Cheng-Ting CHUNG, Hsinchu (TW); Hou-Yu CHEN, Hsinchu (TW); Jin CAI, Hsinchu (TW); Chih-Hao WANG, Hsinchu (TW)

(73) Assignee: Taiwan Semiconductor Manufacturing Co., Ltd., Hsinchu (TW)

(21) Appl. No.: 19/224,212

(22) Filed: May 30, 2025

Related U.S. Application Data
(60) Provisional application No. 63/766,199, filed on Mar. 3, 2025.

(51) Int. Cl. H10D 64/27; H10D 30/00; H10D 30/01; H10D 30/43; H10D 62/10; H10D 62/17; H10D 84/01; H10D 84/85

(52) U.S. Cl. CPC H10D 64/518; H10D 30/014; H10D 30/0191; H10D 30/43; H10D 30/502; H10D 62/121; H10D 62/235; H10D 64/513; H10D 84/0167; H10D 84/017; H10D 84/0186; H10D 84/0188; H10D 84/851

(57) ABSTRACT

An integrated circuit includes a complimentary field effect transistor (CFET). The CFET includes a first transistor including a pair of first source/drain regions and a plurality of stacked first channels extending in the first lateral direction between the pair of first source/drain regions. The CFET includes a second transistor above the first transistor and including a pair of second source/drain regions and a plurality of stacked second channels extending in the first lateral direction between the pair of second source/drain regions. The CFET includes gate spacer layers defining a gate trench adjacent to the second channels and a gate metal in the gate trench and between the second channels. The gate metal has a first length in the first lateral direction in the gate trench and a second length in the first lateral direction between the second channels. The first length is greater than the second length.

### BACKGROUND

There has been a continuous demand for increasing computing power in electronic devices including smart phones, tablets, desktop computers, laptop computers and many other kinds of electronic devices. Integrated circuits provide the computing power for these electronic devices. One way to increase computing power in integrated circuits is to increase the number of transistors and other integrated circuit features that can be included for a given area of semiconductor substrate.

Complementary field effect transistors (CFETs) may be utilized to increase the density of transistors in an integrated circuit. A CFET may include an N-type transistor and a P-type transistor stacked vertically. The gate electrodes of the N-type and P-type transistors may be electrically shorted together.

However, there are various difficulties associated with the formation of CFETs. For example, as scaling continues, there is the potential for reduced carrier mobility in channels. Furthermore, the short channel effect can also increase.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of the inventor's approach to the particular problem, which, in and of itself, may also be inventive.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B and FIGS. 2A-30B are cross-sectional and top views of an integrated circuit at intermediate stages of a process for forming a CFET, in accordance with some embodiments.

FIGS. 1C-1E are illustrations of a unit cell of monocrystalline silicon, in accordance with some embodiments.

FIG. 31 is a flow diagram of a method for forming an integrated circuit, in accordance with some embodiments.

FIG. 32 is a flow diagram of a method for forming an integrated circuit, in accordance with some embodiments.

### DETAILED DESCRIPTION

In the following description, many thicknesses and materials are described for various layers and structures within an integrated circuit die. Specific dimensions and materials are given by way of example for various embodiments. Those of skill in the art will recognize, in light of the present disclosure, that other dimensions and materials can be used in many cases without departing from the scope of the present disclosure.

The following disclosure provides many different embodiments, or examples, for implementing different features of the described subject matter. Specific examples of components and arrangements are described below to simplify the present description. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, certain specific details are set forth in order to provide a thorough understanding of various embodiments of the disclosure. However, one skilled in the art will understand that the disclosure may be practiced without these specific details. In other instances, well-known structures associated with electronic components and fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second and third does not necessarily imply a ranked sense of order, but rather may only distinguish between multiple instances of an act or structure.

Reference throughout this specification to “one embodiment” or “an embodiment” means that a particular feature, structure or characteristic described in connection with the embodiment is included in at least some embodiments. Thus, the appearances of the phrases “in one embodiment”, “in an embodiment”, or “in some embodiments” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

Embodiments of the present disclosure provide an integrated circuit including a CFET with improved electrical characteristics. The CFET includes an NFET transistor and a PFET transistor stacked together. Embodiments of the present disclosure provide a CFET in which the inner gate length is shorter than the outer gate length and in which the channels have reduced vertical thicknesses. Embodiments of the present disclosure also provide a CFET having different crystal orientations for the channels of the PFET and NFET transistors.

The reduced inner gate length helps reduce the undesirable short channel effect. The different crystal orientations for the PFET channels and the NFET channels help ensure that both the NFET charge carriers and the PFET charge carriers have strong mobility. This further enables the reduced vertical thickness of the channels, resulting in smaller stacking heights. The result is integrated circuits with dense arrays of properly functioning CFETs with good conduction and switching characteristics. This leads to better performing devices and higher wafer yields.

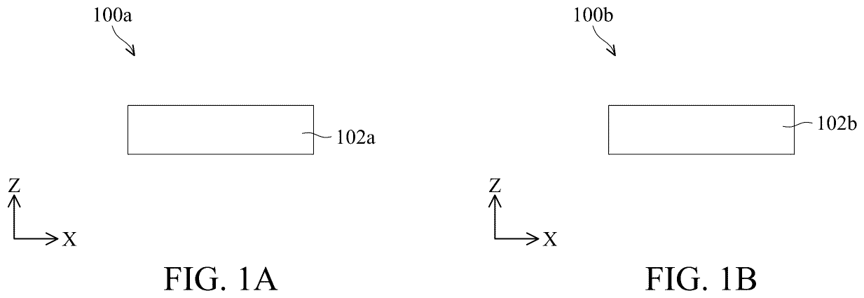

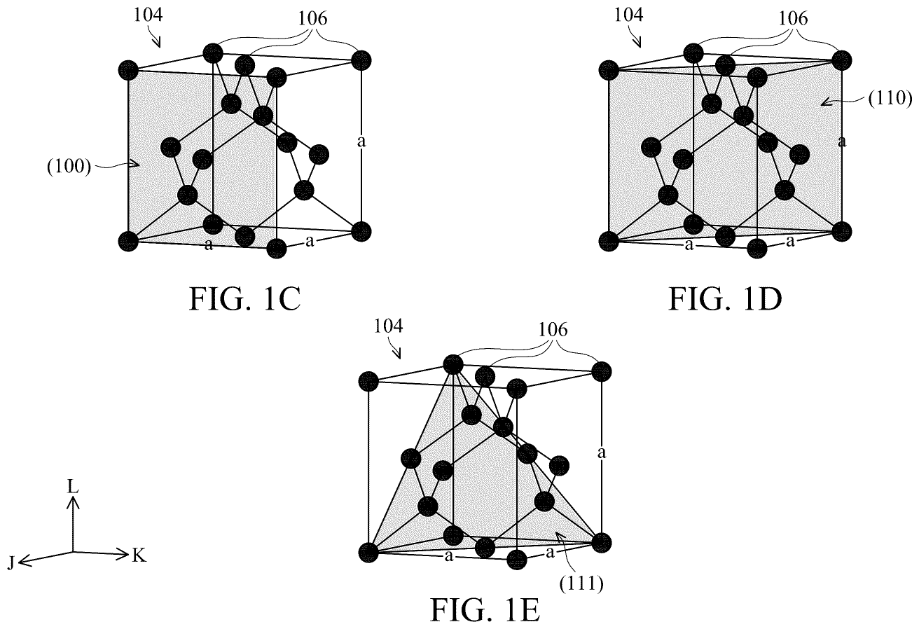

FIGS. 1A-1B and FIGS. 2A-17D are cross-sectional and top views of an integrated circuit at intermediate stages of a process for forming a CFET, in accordance with some embodiments.

The CFET transistor may correspond to a gate all around transistor. The gate all around transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the gate all around structure. Furthermore, the gate all around CFET 101 may include a plurality of semiconductor nanostructures corresponding to channel regions of the CFET 101. The semiconductor nanostructures may include nanosheets, nanowires, or other types of nanostructures. The gate all around transistors may also be termed nanostructure transistors.

FIG. 1A is a cross-sectional view of a first wafer 100a including a first semiconductor substrate 102a. FIG. 1B is a cross-sectional view of a second wafer 100b including a second semiconductor substrate 102b. As will be set forth in more detail below, the wafers 100a and 100b will eventually be bonded together to form a compound wafer 101 in which the CFETs are formed.

In some embodiment, the semiconductor substrates 102a and 102b include a same semiconductor material. The substrates 102a and 102b can each include a single crystalline semiconductor layer on at least a surface portion. The substrates 102a and 102b may include a single crystalline semiconductor material such as, but not limited to Si, Ge, SiGe, GaAs, InSb, GaP, GaSb, InAlAs, InGaAs, GaSbP, GaAsSb and InP. In a primary example illustrated herein, the substrates 102a and 102b each include a monocrystalline silicon, though other materials can be utilized without departing from the scope of the present disclosure.

In some embodiments, the substrate 102a will be utilized to grow a stack of semiconductor layers that will be utilized for a PFET transistor of the CFET. The semiconductor layers will be grown with an epitaxial growth process from the substrate 102a. Accordingly, the semiconductor layers will carry a crystalline structure of the substrate 102a. In an example in which the semiconductor layers grown from the substrate 102a will be utilized to form channels of a PFET transistor, it is beneficial to select an orientation of the crystalline structure of the substrate 102a to promote high mobility of holes (P-type charge carriers) traveling in the X-direction through the channels. As used herein, the orientation of the crystalline structure corresponds to the orientation at the X-Y plane of the top surface of the substrate 102a prior to growth of the epitaxial layers.

In some embodiments, the substrate 102b will be utilized to grow a stack of semiconductor layers that will be utilized for an NFET transistor of the CFET. The semiconductor layers will be grown with an epitaxial growth process from the substrate 102b. Accordingly, the semiconductor layers will carry a crystalline structure of the substrate 102b. In an example in which the semiconductor layers grown from the substrate 102b will be utilized to form channels of an NFET transistor, it is beneficial to select the orientation of the crystalline structure of the substrate 102b to promote high mobility of electrons (P-type charge carriers) traveling in the X-direction through the channels. As used herein, the orientation of the crystalline structure corresponds to the orientation of the X-Y plane of the top surface of the substrate 102b prior to growth of the epitaxial layers. In some embodiments, the orientation of the crystalline structure of the substrate 102b is different than the orientation of the crystalline structure of the substrate 102a.

FIGS. 1C-1E are illustrations of a unit cell 104 of monocrystalline silicon. The unit cell 104 includes a plurality of silicon atoms 106. The unit cell 104 is cubic with sides of length a. In some embodiments, a has a value of 5.431 Å. FIGS. 1C-1E also utilize a coordinate system of three mutually orthogonal axes labeled j, k, and l. FIG. 1C illustrates the 100 plane. FIG. 1D illustrates the plane 110. FIG. 1E illustrates the 111 plane.

The substrates 102a and 102b each have a crystal orientation, in accordance with some embodiments. The crystal orientation of the substrate corresponds to the plane (e.g., 100, 110, 111, etc.) that makes up the top surface (X-Y) plane of the substrate. In one example, NFET devices have a higher electron mobility in the X-direction when the silicon channels have a 100 orientation. In one example, PFET devices have a higher hole mobility in the X direction when the silicon channels have a 110 orientation. In some embodiments, the substrate 102a will be utilized for PFET devices and has a crystal orientation of 110. In some embodiments, the substrate 102 b will be utilized for NFET devices, and has a crystal orientation of 100. Other materials and orientations can be utilized without departing from the scope of the present disclosure.

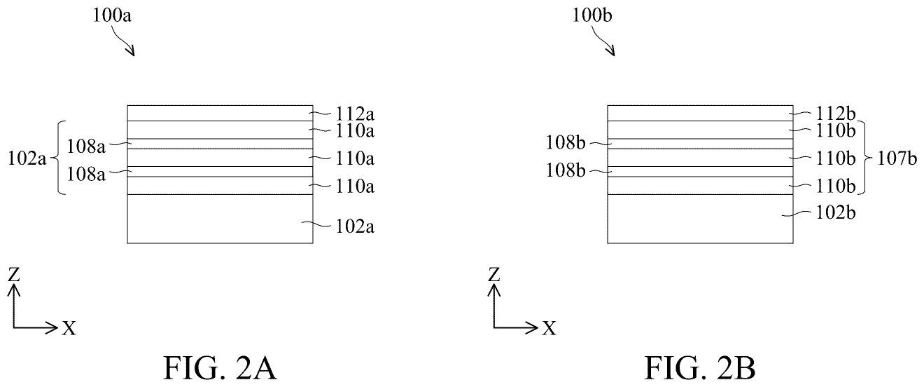

FIG. 2A is a cross-sectional view of the wafer 100a, in accordance with some embodiments. In some embodiments, the semiconductor substrate 102a is a monocrystalline silicon with an orientation of 110. In FIG. 2A a stack 107a of semiconductor layers has been formed over the substrate 102, in accordance with some embodiments. The stack 107a can be formed by performing a series of epitaxial growth processes from the substrate 102a to form the layers of the stack 107a. The stack 107a includes a plurality of semiconductor layers 108a and sacrificial semiconductor layers 110a interleaved together. As will be set forth in more detail below, the semiconductor layers 108a will be patterned to form stacked channels of a first transistor of a CFET. As will be set forth in more detail below, the sacrificial semiconductor layers 110a will be patterned and eventually replaced with gate metals wrapped around the channels.

In some embodiments, the semiconductor layers 108a include silicon. Because the semiconductor layers 108a are grown epitaxially from the substrate 102a, the semiconductor layers 108a have a same crystal orientation (e.g., 110) as the substrate 102a. In some embodiments, the semiconductor layers 108a have a vertical thickness between 0.5 nm and 8 nm. Other materials, thicknesses, and orientations can be utilized without departing from the scope of the present disclosure.

In some embodiments, the sacrificial semiconductor layers 110a include a material that is selectively etchable with respect to the material of the semiconductor layers 108a. In some embodiments, the sacrificial semiconductor layers 110a include silicon germanium. Other materials can be utilized without departing from the scope of the present disclosure.

A bonding dielectric layer 112a has been formed on the stack 107a, in accordance with some embodiments. The bonding dielectric layer 112a includes one or more of SiO, SiN, SiCN, SiOCN, or other suitable dielectric materials. The bonding dielectric layer 112a can be formed by atomic layer deposition (ALD), chemical vapor deposition (CVD), physical vapor deposition (PVD), or other suitable deposition processes. The bonding dielectric layer 112a may have a thickness between 10 nm and 30 nm, though other thicknesses can be utilized without departing from the scope of the present disclosure.

FIG. 2B is a cross-sectional view of the wafer 100b, in accordance with some embodiments. In some embodiments, the semiconductor substrate 102b is a monocrystalline silicon with an orientation of 100. In FIG. 2B a stack 107b of semiconductor layers has been formed over the substrate 102, in accordance with some embodiments. The stack 107b can be formed by performing a series of epitaxial growth processes from the substrate 102b to form the layers of the stack 107b. The stack 107b includes a plurality of semiconductor layers 108b and sacrificial semiconductor layers 110b interleaved together. As will be set forth in more detail below, the semiconductor layers 108b will be patterned to form stacked channels of a second transistor of a CFET. As will be set forth in more detail below, the sacrificial semiconductor layers 110b will be patterned and eventually replaced with gate metals wrapped around the channels.

In some embodiments, the semiconductor layers 108b include silicon. Because the semiconductor layers 108b are grown epitaxially from the substrate 102b, the semiconductor layers 108b have a same crystal orientation (e.g., 100) as the substrate 102b. In some embodiments, the semiconductor layers 108 b have a vertical thickness between 0.5 nm and 8 nm. Other materials, thicknesses, and orientations can be utilized without departing from the scope of the present disclosure.

In some embodiments, the sacrificial semiconductor layers 110b include a material that is selectively etchable with respect to the material of the semiconductor layers 108b. In some embodiments, the sacrificial semiconductor layers 110b include silicon germanium. Other materials can be utilized without departing from the scope of the present disclosure.

A bonding dielectric layer 112b has been formed on the stack 107b, in accordance with some embodiments. The bonding dielectric layer 112b includes one or more of SiO, SiN, SiON, SiCN, SiOCN, or other suitable dielectric materials. The bonding dielectric layer 112b can be formed by atomic layer deposition (ALD), chemical vapor deposition (CVD), physical vapor deposition (PVD), or other suitable deposition processes. The bonding dielectric layer 112b may have a thickness between 10 nm and 30 nm, though other thicknesses can be utilized without departing from the scope of the present disclosure.

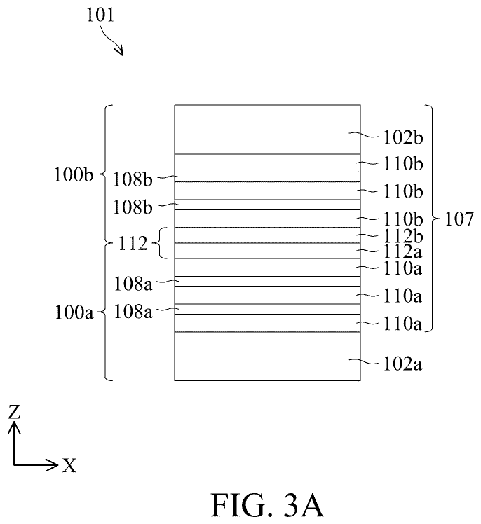

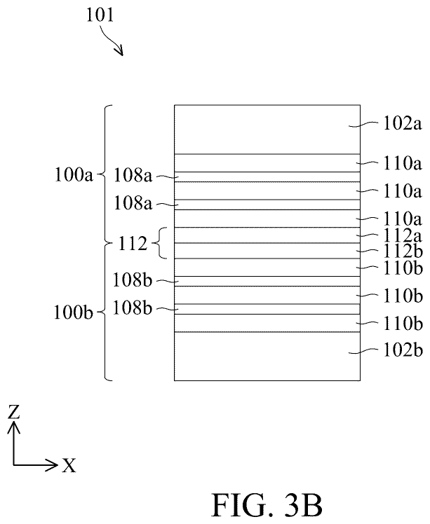

In FIG. 3A, the wafers 100a and 100b. Have been bonded together to form a compound wafer 101, in accordance with some embodiments. The wafer 102b has been flipped so that the bonding dielectric layer 112b faces downward. The wafers 100a and 100b are then stacked so that the bonding dielectric layer 112a is in contact with the bonding dielectric layer 112b. Subsequently, a thermal annealing process is performed to bond the dielectric layers 112a and 112b into a single middle dielectric isolation layer 112. As will be set forth in more detail below, the middle dielectric isolation layer 112 serves as a dielectric isolation between the PFET transistor and the NFET transistor of the CFET.

FIG. 3B illustrates an alternative embodiment in which the wafer 100a is on top of the wafer 100b in the compound wafer 101.

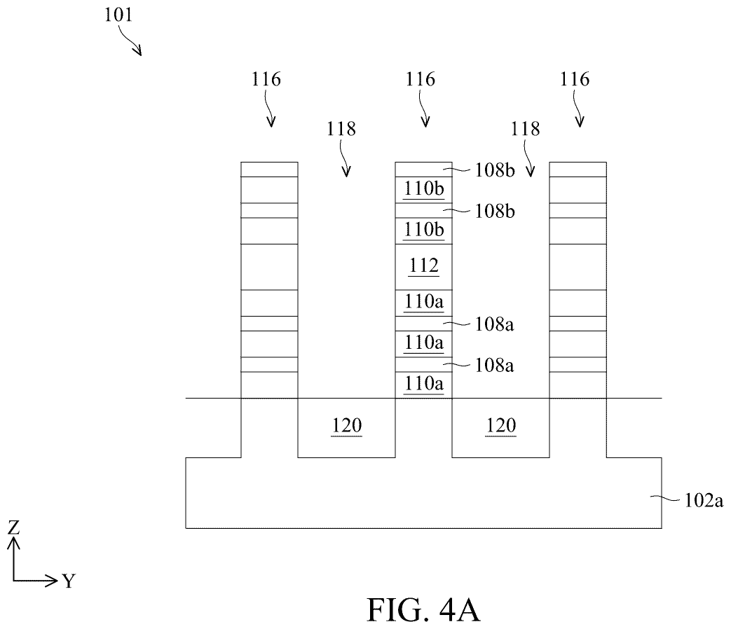

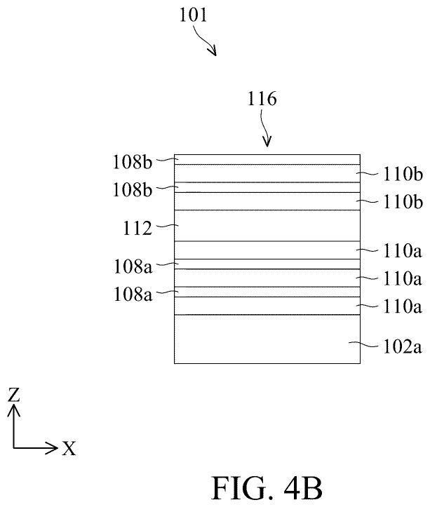

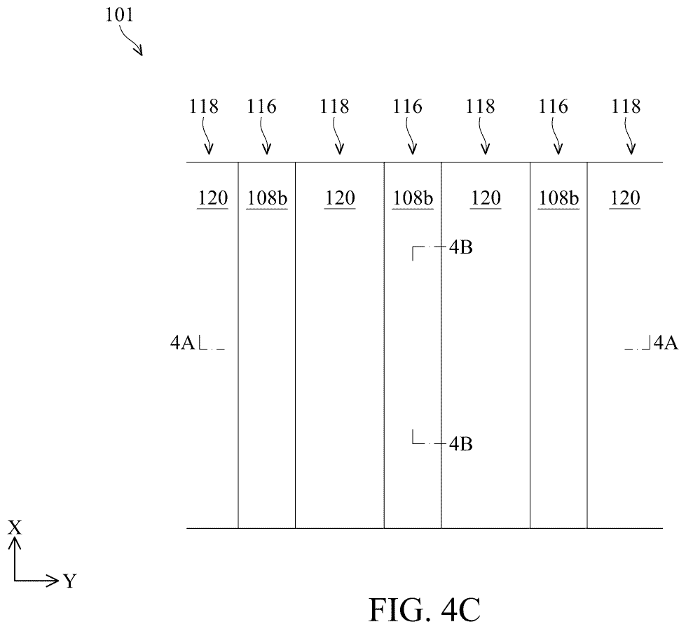

FIGS. 4A and 4B are cross-sectional views of the compound wafer 101, in accordance with some embodiments. FIG. 4C is a top view of the compound wafer 101, in accordance with some embodiments. The cross-sectional views of FIGS. 4A and 4B are taken along cut lines 4A and 4B of FIG. 4C.

In FIG. 4A, the semiconductor substrate 102b has been removed, in accordance with some embodiments. The top sacrificial semiconductor layer 110b has also been removed. However, in some embodiments, the top sacrificial semiconductor layer 110b is not removed.

In FIG. 4A, a plurality of fins 116 have been formed from the stack 107, in accordance with some embodiments. The fins 116 can be formed in conjunction with a photolithography process in which a mask is formed and patterned over the stack 107. An etching process is then performed to etch in the downward direction to form trenches 118 at the locations exposed by the mask. The fins 116 are formed by forming the trenches 118. The trenches 118 extend into the substrate 102a. Each fin 116 is an active region extending lengthwise in the X direction.

In FIG. 4A, dielectric isolation structures 120 have been formed in recesses in the trenches 118, in accordance with some embodiments. Initially, the material of the dielectric isolation structures 120 may completely cover the fins 116. Subsequently, an etchback process is performed to reduce the top surface of the dielectric isolation structures 120 to the level shown in FIG. 4A. The dielectric isolation structures 120 can include silicon oxide or another suitable dielectric material. In some embodiments, the dielectric isolation structures 120 correspond to shallow trench isolation regions.

The cross-sectional view of FIG. 4B illustrates that the layers 108a/b, 110a/b, and 113, extend in the X direction, in accordance with some embodiments. In other words, the fins 116 extend in the X direction.

The top view of FIG. 4C illustrates the fins 116 extending in the X direction with the top semiconductor layer 108 be exposed, in accordance with some embodiments. The trenches 118 extend in the X direction between the fins 116, with the dielectric isolation structures 120 exposed.

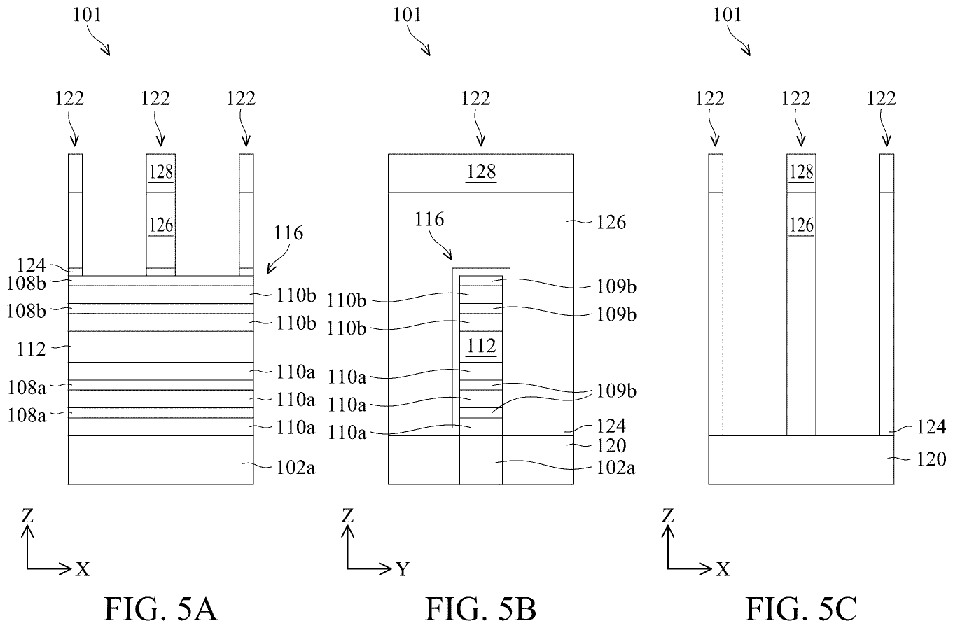

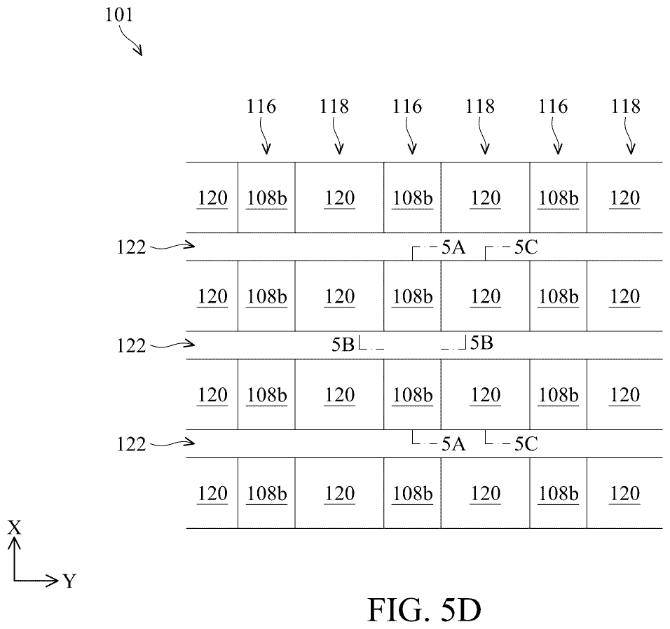

FIGS. 5A-5C are cross-sectional views of the wafer 101, in accordance with some embodiments. FIG. 5D is a top view of the wafer 101. The cross-sectional views of FIGS. 5A-5C are taken along cut lines 5A-5C of FIG. 5D, in accordance with some embodiments.

In FIGS. 5A-5D, a plurality of sacrificial gate structures 122 have been formed, in accordance with some embodiments. The sacrificial gate structures 122 extend in the Y direction across the trenches 118 and the fins 116. The sacrificial gate structures 122 include a dielectric layer 124, a sacrificial gate layer 126, and a dielectric layer 128.

In some embodiments, the dielectric layer 124 includes one or more of SiO, SiN, SiON, SiCN, SiOCN, or other suitable dielectric materials. The dielectric layer 124 is formed by CVD, ALD, PVD, or other suitable deposition processes.

The sacrificial gate layer 126 can include materials that have a high etch selectivity with respect to the isolation structures 120. In an exemplary embodiment, the sacrificial gate layer 126 includes polysilicon. However, the sacrificial gate layer 126 may be a conductive, semiconductive, or non-conductive material and may be or include amorphous silicon, poly-crystalline silicon-germanium (poly-SiGe), metallic nitrides, metallic silicides, metallic oxides, and metals. The sacrificial gate layer 126 may be deposited by physical vapor deposition (PVD), CVD, sputter deposition, or other techniques for depositing the selected material.

The sacrificial gate structures 122 include a dielectric layer 128 on the sacrificial gate layer 126, in accordance with some embodiments. The dielectric layer 128 includes one or more of SiN, SiON, SiCN, SiOCN, SiOC, or other suitable dielectric materials. The dielectric layer 128 can be deposited by ALD, CVD, PVD, or other suitable deposition processes.

The sacrificial gate structure 122 is referred to as a sacrificial gate structure because the gate electrodes of the PFET and NFET transistors of the CFET will be formed, in part, in place of the sacrificial gate layer 126.

The sacrificial gate structure 122 may also include one or more additional dielectric layers above the sacrificial gate layer 126. Various configurations and materials can be utilized for the sacrificial gate structure 122 without departing from the scope of the present disclosure.

The cross-sectional view of FIG. 5B illustrates a sacrificial gate structure 122 covering the top and side walls of a thin 116, in accordance with some embodiments. The cross-sectional view of FIG. 5C illustrates a plurality of sacrificial gate structures 122 extending in the Y direction across a trench 118 on the top surface of the dielectric isolation structure 120. FIG. 5D illustrates the sacrificial gate structures 122 extending across the trenches 118 and the semiconductor fins 116, with the various exposed layers.

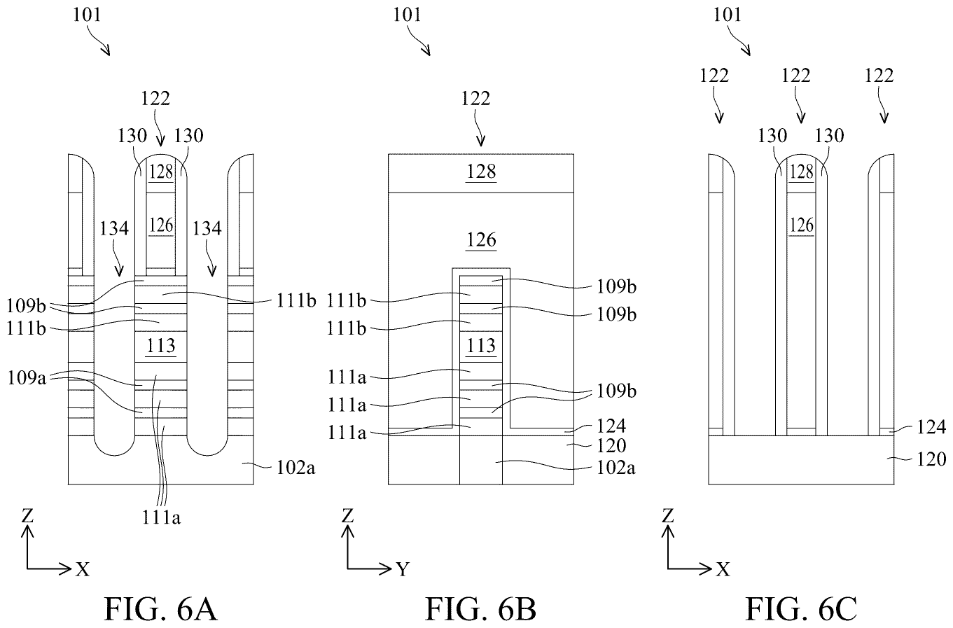

FIGS. 6A-6C are cross-sectional views of the wafer 101, in accordance with some embodiments. The cross-sectional views of FIGS. 6A-6C correspond to the cut lines 5A-5C, though at a further stage of processing.

In FIGS. 6A-6C, a gate spacer layer 130 has been formed on sidewalls of the sacrificial gate layer 126. In one example, the gate spacer layer 130 includes silicon nitride. Alternatively, the gate spacer layer 130 can include silicon oxide, silicon oxynitride, silicon carbonitride, silicon oxycarbonitride, fluorine-doped silicate glass (FSG), or another suitable dielectric material. The gate spacer layer 130 may include multiple dielectric layers. The gate spacer layer 130 may also be termed a sidewall spacer.

In FIG. 6A, an etching process has been performed to form source/drain trenches 134 in the fins 116. In particular, the etching process removes the portions of the sacrificial semiconductor layers 110a/b and semiconductor layers 108a/b that are not directly below the gate spacer layer 130. The etching process can include an anisotropic etch that selectively etches in the downward (z−)direction. The source/drain trenches 134 extend into the substrate 102a.

Formation of the source/drain trenches 134 results in formation of a plurality of stacks of channels 109a from the semiconductor layers 108a, sacrificial semiconductor nanostructures 111a from the sacrificial semiconductor layers 110a, stacks of channels 109b from the semiconductor layers 108b, sacrificial semiconductor nanostructures 111b from the sacrificial semiconductor layers 110b, and a middle isolation structure 113 from the middle isolation layer 112.

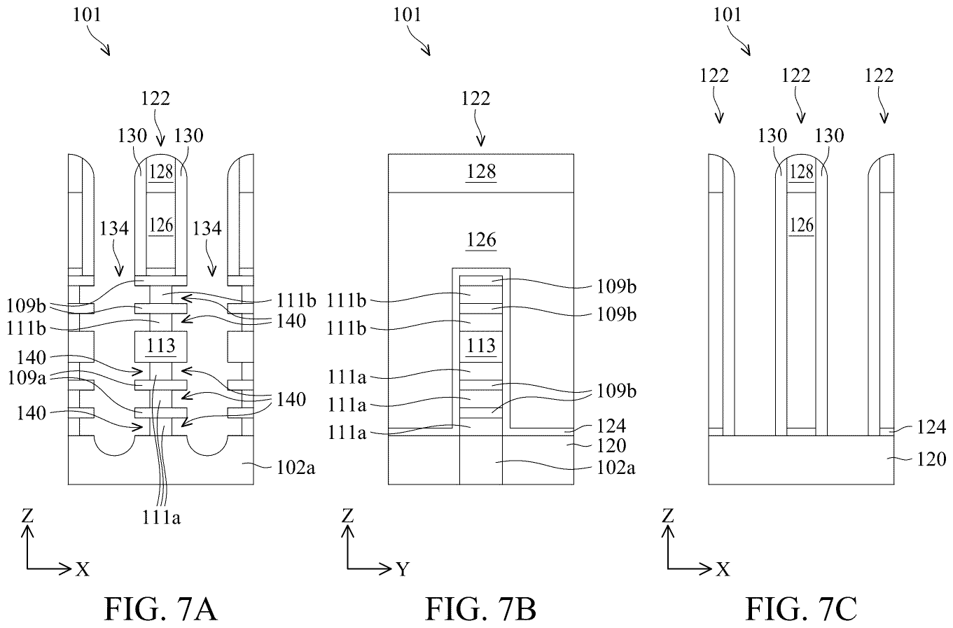

FIGS. 7A-7C are cross-sectional views of the wafer 101, in accordance with some embodiments. The cross-sectional views of FIGS. 7A-7C correspond to the cut lines 5A-5C, though at a further stage of processing.

In FIG. 7A, an isotropic etching process is performed to form recesses 140 in the sacrificial semiconductor nanostructures 111a/b. The isotropic etching process selectively etches the material of the sacrificial semiconductor nanostructures 111a/b with respect to the channels 109a/b. The isotropic etching process is a timed process that recesses the sacrificial semiconductor nanostructures 111a/b without entirely removing the sacrificial semiconductor nanostructures 111a/b.

As can be seen in FIG. 7A, the sacrificial gate layer 126 is wider in the X direction than are the remaining portions of the sacrificial semiconductor nanostructures 111a/b. As will be set forth in more detail below, the width of the sacrificial gate layer 126 in the X direction correlates to an outer gate length, as the sacrificial gate layer 126 will eventually be replaced by a gate metal. The width of the sacrificial semiconductor nanostructures 111a/b correlates with an inner gate length, as the sacrificial semiconductor nanostructures 111a/b will eventually be replaced by a gate metal. The recessing step is selected to form recesses 140 with a depth in the X direction that results in the sacrificial semiconductor nanostructures 111a/b having a width in the X direction that is smaller than the width of the sacrificial gate layer 126.

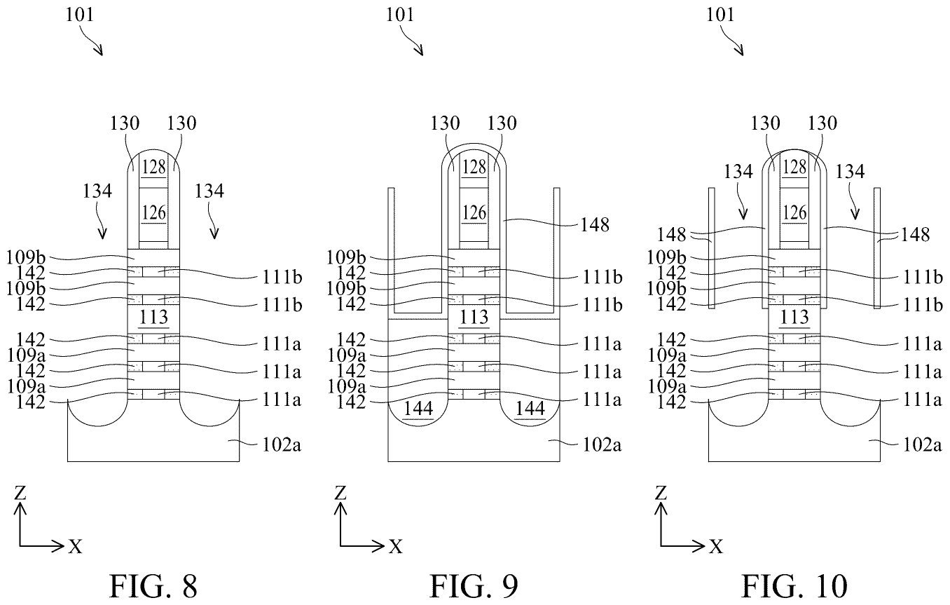

FIG. 8 is cross-sectional views of the wafer 101, in accordance with some embodiments. The cross-sectional views of FIG. 8 corresponds to the cut line 5A, though at a further stage of processing. In FIG. 8, inner spacers 142 have been formed in the recesses 140 of the sacrificial semiconductor nanostructures 111a/b. The inner spacers 142 can be formed by depositing a dielectric layer on the exposed sidewalls of the channels 109a/b, on sidewalls of the gate spacers 130, and in the recesses 140 formed in the sacrificial semiconductor nanostructures 111a/b. The dielectric layer can include silicon oxide, silicon nitride, silicon oxynitride, silicon carbonitride, silicon oxycarbonitride, FSG, a low-K dielectric material or other dielectric materials without departing from the scope of the present disclosure. The dielectric layer can be formed by CVD, PVD, ALD, or via another process. The lateral thickness (in the x-direction) of the dielectric layer may be between 2 nm and 10 nm. Other thicknesses, materials, and deposition processes can be utilized for the dielectric layer without departing from the scope of the present disclosure.

An etching process is then performed to remove portions of the dielectric layer that are not vertically below a channel 109a/b or the middle isolation structure 113. The etching process defines the inner spacers 142 as shown in FIG. 8. Other processes can be utilized to form the inner spacers 142 without departing from the scope of the present disclosure.

FIG. 9 is cross-sectional views of the wafer 101, in accordance with some embodiments. The cross-sectional views of FIG. 9 corresponds to the cut line 5A, though at a further stage of processing. In FIG. 9, sacrificial source/drain structures 144 have been formed in the source/drain trenches 134. The sacrificial source/drain structures 144 can include a dielectric material such as SiO, SiN, SiON, SiCN, SiOCN, FSG, or another suitable dielectric material. The sacrificial source/drain structures 144 can be deposited by CVD, ALD, PVD, or another suitable deposition process. The top surface of the sacrificial source/drain structures 144 is intermediate to the middle isolation structure 113.

In FIG. 9, a dielectric layer 148 has been deposited conformally deposited on the sacrificial source/drain structures, on sidewalls of the channels 109b and exposed inner spacers 142, and on the gate spacer layer 130. The dielectric layer 148 includes one or more of SiO, SiN, SiON, SiCN, SiOCN, FSG, or another suitable dielectric material. The dielectric layer 148 is deposited by CVD, ALD, PVD, or another suitable deposition process.

FIG. 10 is cross-sectional views of the wafer 101, in accordance with some embodiments. The cross-sectional views of FIG. 10 corresponds to the cut line 5A, though at a further stage of processing. In FIG. 10, an anisotropic etching process has been performed to remove the portions of the dielectric layer 148 from the top surfaces of the sacrificial source/drain structures 144. The anisotropic etching process does not remove the vertically thicker portions of the dielectric layer 148 from the sidewalls of the gate spacers 130, channels 109b, and inner spacers 142.

In FIG. 10, an etching process has been performed to remove the sacrificial source/drain structures 144. The result is that end portions of the channels 109a, and the substrate 102a are exposed. The etching process can be the same etching process or different etching process as the etching process that removes portions of the dielectric layer 148.

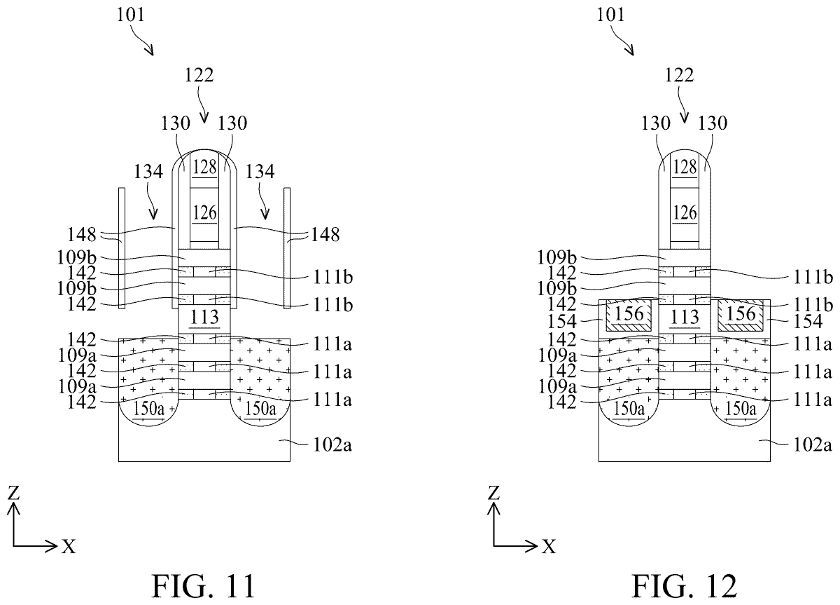

FIG. 11 is cross-sectional views of the wafer 101, in accordance with some embodiments. The cross-sectional views of FIG. 11 corresponds to the cut line 5A, though at a further stage of processing. In FIG. 11, source/drain regions 150 a have been formed in the lower portion of the source/drain trenches 134.

In FIG. 11, source/drain regions 150a have been formed, in accordance with some embodiments. The source/drain regions 150a may be formed in an epitaxial growth process from the channels 109a and the substrate 102a. The source/drain regions 150a include a semiconductor material. The semiconductor material can include a same semiconductor material as the channels 109a. Alternatively, the semiconductor material of the source/drain regions 150a can be different than the semiconductor material of the channels 109a. The source/drain regions 109a may be doped in situ with dopant atoms during the epitaxial growth process. In the example in which the lower transistor is a P-type transistor, the source/drain regions 150a may be doped in situ with P-type dopant atoms. The P-type dopant atoms can include boron or other P-type dopant atoms.

FIG. 12 is cross-sectional views of the wafer 101, in accordance with some embodiments. The cross-sectional views of FIG. 12 corresponds to the cut line 5A, though at a further stage of processing. In FIG. 12, the dielectric layer 148 has been removed. This exposes sidewalls of the channels 109b.

In FIG. 12, a contact etch stop layer (CESL) 154 has been deposited. The CESL 154 is initially conformally deposited on all exposed surfaces. The CESL 154 is deposited by CVD, ALD, PVD, or another suitable deposition process. The CESL 154 includes one or more of SiN, SiON, SiOCN, SiCN, or other suitable dielectric materials.

In FIG. 12, an interlevel dielectric layer 156 has been deposited. The interlevel dielectric layer 156 is deposited on the CESL 154. The interlevel dielectric layer 156 is deposited by CVD, ALD, PVD, or another suitable deposition process. The interlevel dielectric layer 156 includes one or more of SiO, SiN, SiON, SiOCN, SiCN, FSG, or other suitable dielectric materials.

In FIG. 12, an etchback process has been performed. The etchback process recesses the top surfaces of the CESL 158 and the interlevel dielectric layer 156 to a level lower than the lowest channel 109b. Accordingly, end portions of the channels 109b remain exposed.

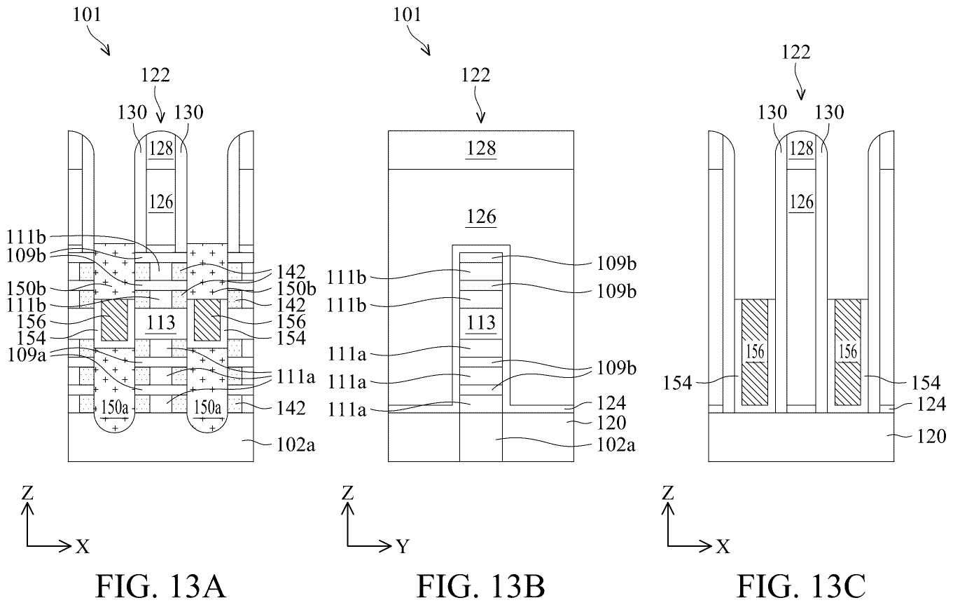

FIGS. 13A-13C are cross-sectional views of the wafer 101, in accordance with some embodiments. The cross-sectional views of FIGS. 13A-13C correspond to the cut lines 5A-5C, though at a further stage of processing.

In FIG. 13A, source/drain regions 150b have been formed, in accordance with some embodiments. The source/drain regions 150b may be formed in an epitaxial growth process from the channels 109b. The source/drain regions 150b include a semiconductor material. The semiconductor material can include a same semiconductor material as the channels 109. Alternatively, the semiconductor material of the source/drain regions 150b can be different than the semiconductor material of the channels 109b. The source/drain regions 150b may be doped in situ with dopant atoms during the epitaxial growth process. In an example in which the upper transistor is an N-type transistor, the source/drain regions 150b may be doped in situ with N-type dopant atoms. The dopant atoms can include phosphorus, arsenic, or other N-type dopant atoms. As set forth previously, in some embodiments, alternatively, the lower transistor is an N-type transistor and the upper transistor is a P-type transistor.

FIG. 13C illustrates the presence of the CESL 154 and the interlevel dielectric layer 156 between sacrificial gate structures 122 on the dielectric isolation structure 120.

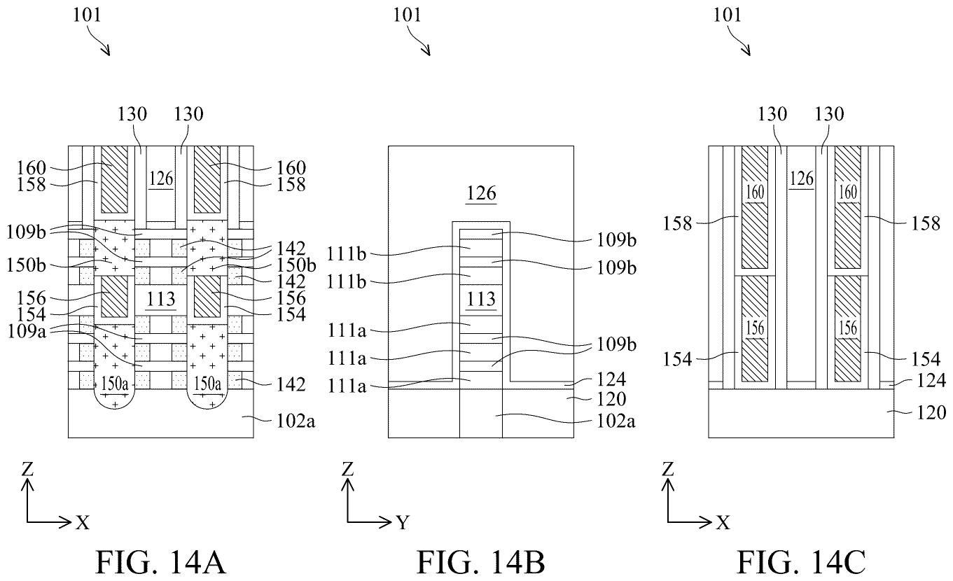

FIGS. 14A-14C are cross-sectional views of the wafer 101, in accordance with some embodiments. The cross-sectional views of FIGS. 14A-14C correspond to the cut lines 5A-5C, though at a further stage of processing.

In FIGS. 14A-14C, an interlevel dielectric layer 156 has been deposited. The interlevel dielectric layer 156 is deposited on the CESL 154. The interlevel dielectric layer 156 is deposited by CVD, ALD, PVD, or another suitable deposition process. The interlevel dielectric layer 156 includes one or more of SiO, SiN, SiON, SiOCN, SiCN, FSG, or other suitable dielectric materials.

In FIGS. 14A-14C, a CESL 158 has been deposited. The CESL 158 is initially conformally deposited on all exposed surfaces. The CESL 158 is deposited by CVD, ALD, PVD, or another suitable deposition process. The CESL 158 includes one or more of SiN, SiON, SiOCN, SiCN, or other suitable dielectric materials.

In FIGS. 14A-14C, an interlevel dielectric layer 160 has been deposited. The interlevel dielectric layer 160 is deposited on the CESL 158. The interlevel dielectric layer 160 is deposited by CVD, ALD, PVD, or another suitable deposition process. The interlevel dielectric layer 158 includes one or more of SiO, SiN, SiON, SiOCN, SiCN, FSG, or other suitable dielectric materials.

In FIGS. 14A-14C, a CMP process has been performed. The CMP process. Planarized is the top surfaces of the CESL 158, the interlevel dielectric layer 160, the gate spacer layer 130, and the sacrificial gate structure 126. The dielectric layer 128 is removed by the CMP process.

FIG. 14A, illustrates that the CESL 158 is on the top surface of the source/drain regions 150b. FIG. 14C illustrates that the CESL is on the top surface of the CESL 154 and the interlevel dielectric layer 156.

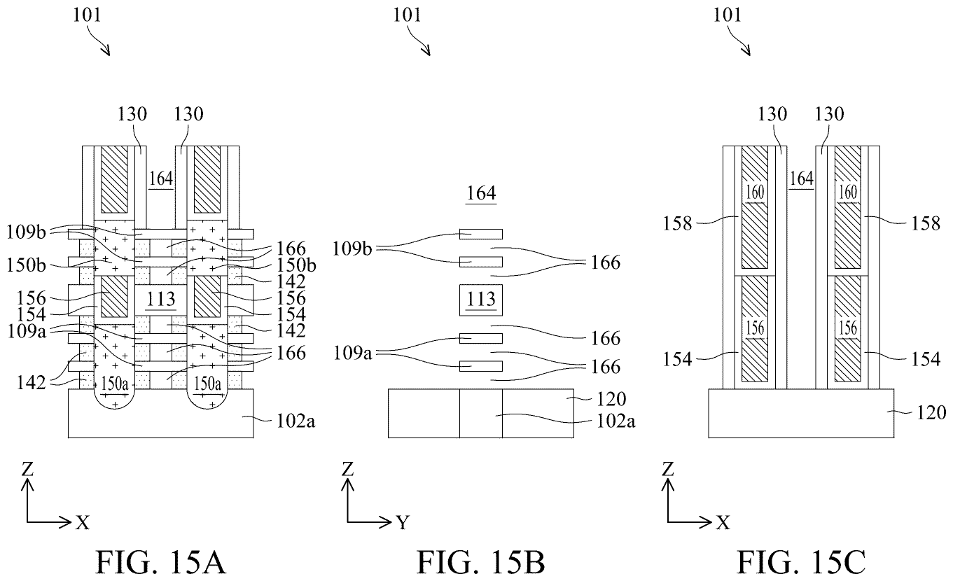

FIGS. 15A-15C are cross-sectional views of the wafer 101, in accordance with some embodiments. The cross-sectional views of FIGS. 15A-15C correspond to the cut lines 5A-5C, though at a further stage of processing.

In 15A-15C, the sacrificial gate layer 126 has been removed, in accordance with some embodiments. The sacrificial gate layer 126 can be removed by an etching process that selectively etches the material of the sacrificial gate layer 126 with respect to adjacent materials, such as the gate spacer layers 130. Removal of the sacrificial gate layer 126 results in gate trenches 164 between the gate spacer layers 130.

With reference to FIG. 15A, an etching process has been performed to remove the sacrificial semiconductor nanostructures 111a/b, in accordance with some embodiments. The sacrificial semiconductor nanostructures 111a/b can be removed by a selective etching process using an etchant that is selective to the material of the channels 109a/b, such that the sacrificial semiconductor nanostructures 111a/b are removed without substantially etching the channels 109a/b. In some embodiments, the etching process is an isotropic etching process using an etching gas, and optionally, a carrier gas, where the etching gas comprises F₂ and HF, and the carrier gas may be an inert gas such as Ar, He, N₂, combinations thereof, or the like. In some embodiments, the etching process results in a rounding of side surfaces of the channels 109a/b. The etching process also results in gaps between the channels 109a/b.

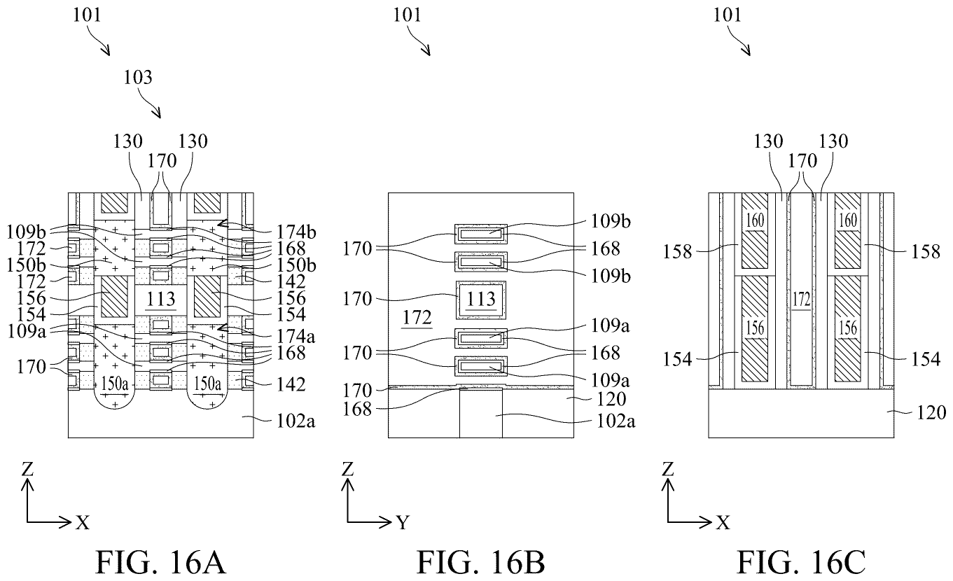

FIGS. 16A-16C are cross-sectional views of the wafer 101, in accordance with some embodiments. The cross-sectional views of FIGS. 16A-16C correspond to the cut lines 5A-5C, though at a further stage of processing.

In FIGS. 16A-16C, a gate dielectric has been formed, in accordance with some embodiments. The gate dielectric includes an interfacial gate dielectric layer 168 and a high-K gate dielectric layer 170. The interfacial gate dielectric layer 168 has been deposited on exposed portions of the channels 109a/b, in accordance with some embodiments. The interfacial gate dielectric layer 168 forms directly on the exposed portions of the channels 109a/b. The high-K gate dielectric layer 170 forms on the interfacial gate dielectric layer 168 and on other exposed surfaces, such as the exposed sidewalls of the gate spacer layer 130, and the inner spacers 148.

The interfacial gate dielectric layer 168 is wrapped around the channels 109a/b. The interfacial gate dielectric layer 168 can include a dielectric material such as silicon oxide, silicon nitride, or other suitable dielectric materials. The interfacial gate dielectric layer 168 can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer 168 can be formed by a thermal oxidation process, a chemical vapor deposition (CVD) process, or an atomic layer deposition (ALD) process. The interfacial gate dielectric layer 168 can have a thickness between 0.5 nm and 2 nm. Other materials, deposition processes, and thicknesses can be utilized for the interfacial gate dielectric layer 168 without departing from the scope of the present disclosure.

The high-K gate dielectric layer 170 is deposited in a conformal deposition process. The conformal deposition process deposits the high-K gate dielectric layer 170 on the interfacial gate dielectric layer 168, on the substrate 102a, on the middle isolation structure 113, on the dielectric isolation structure 120, and on the gate spacer layer 130. The high-K gate dielectric layer 170 is wrapped around the channels 109a/b. The high-K gate dielectric layer 170 has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K gate dielectric layer 170 may be formed by CVD, ALD, or any suitable method. Other thicknesses, deposition processes, and materials can be utilized for the high-K gate dielectric layer 170 without departing from the scope of the present disclosure.

In FIGS. 16A-16C, a gate metal 172 has been deposited, in accordance with some embodiments. The gate metal 172 is deposited in place of the sacrificial gate layer 126 and the sacrificial semiconductor nanostructures 111a/b. Accordingly, the gate metal 172 is positioned in the gate trench above each stack of channels 109a/b. The gate metal 172 is also wrapped around the channels 109a/b of each stack.

In FIGS. 16A-16C, a single gate metal 172 is illustrated as a gate electrode of the transistors 101. However, in practice, the gate metal 172 can include multiple gate metals. For example, the gate metal 172 can include one or more liner layers, one or more work function layers, and a gate fill material that fills the remaining spaces between the gate spacer layers 130. The gate metal 172 can include one or more of Ti, TiN, Ta, TaN, Al, Cu, Co, Ru, W, Au, or other suitable conductive materials. The gate metal 172 can be deposited by PVD, ALD, or CVD. The gate metal 172 may also be termed a gate electrode.

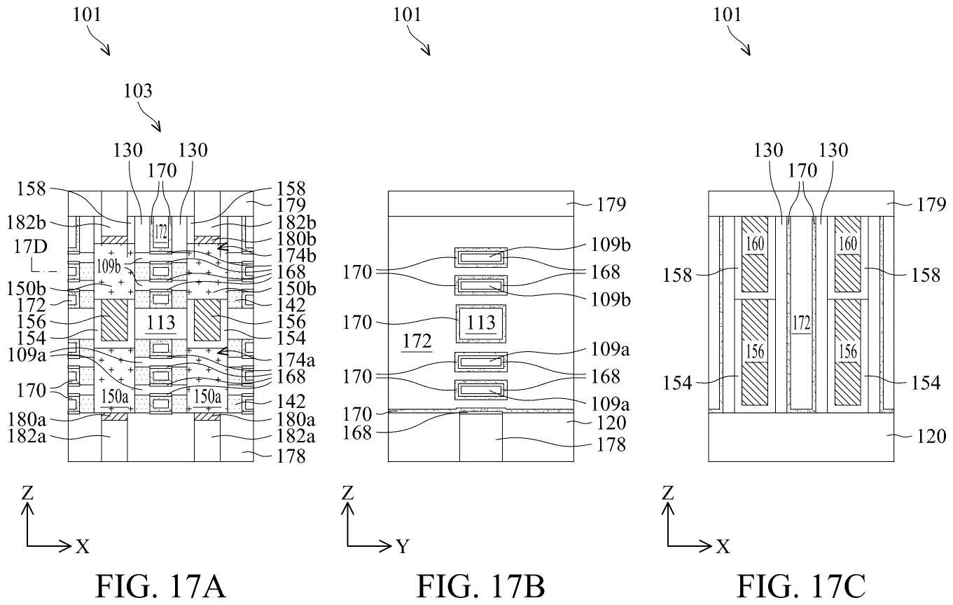

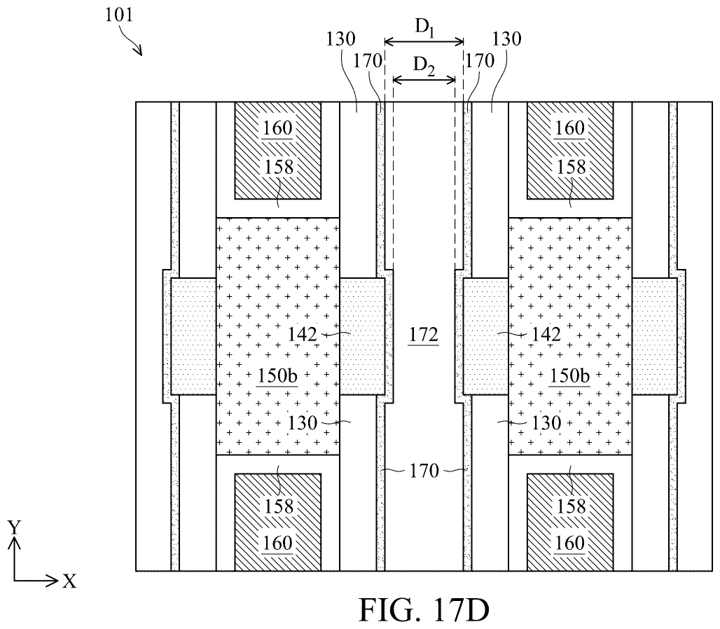

As set forth in further detail in relation to FIG. 17D below, the gate metal has an inner gate length corresponding to the length of the gate metal 172 in the X direction in the gaps 166 between and around the channels 109a/b. The gate metal has an outer gate length corresponding to the length of the gate metal 172 in the gate trench 164 above the channels 109a/b and to the sides of the channels 109b in the Y direction, as can be seen in FIG. 17D. The inner gate length is smaller than the other gate length.

In FIGS. 16A-16C, processing of the CFET 103 is nearly complete. The sea effect 103 includes a lower transistor 174a and an upper transistor 174b. In some embodiments, the upper transistor 174b is an NFET transistor and the lower transistor 174a is a PFET transistor. Alternatively, the lower transistor 174 a is an and loss transistor in the upper transistor 174b is a PFET transistor.

The transistor 174a includes channels 109a extending in the X direction between source/drain regions 150a. The portion of the gate metal 172 wrapped around the channels 109a corresponds to a gate electrode of the transistor 174a. When the transistor 174a is on and current is flowing, the direction of the current is in the X direction between the channels 150a. In the example in which the transistor 174a is a PFET transistor and the channels 109a are silicon, the crystal orientation of the channels 109a is 110. This provides improved mobility of holes traveling in the X direction. This further enables the vertical thickness of the channels 109a to be relatively small without suffering performance penalties. In some embodiments, the vertical thickness of the channels 109a is between 0.5 nm and 8 nm, though other thicknesses can be utilized. Other materials, thicknesses, and crystal orientations can be utilized without departing from the scope of the present disclosure.

The transistor 174b includes channels 109b extending in the X direction between source/drain regions 150b. The portion of the gate metal 172 wrapped around the channels 109b corresponds to a gate electrode of the transistor 174b. When the transistor 174b is on and current is flowing, the direction of the current is in the X direction between the channels 150b. In the example in which the transistor 174b is an NFET transistor and the channels 109b are silicon, the crystal orientation of the channels 109b is 100. This provides improved mobility of electrons traveling in the X direction. This further enables the vertical thickness of the channels 109b to be relatively small without suffering performance penalties. In some embodiments, the vertical thickness of the channels 109b is between 0.5 nm and 8 nm, though other thicknesses can be utilized. Other materials, thicknesses, and crystal orientations can be utilized without departing from the scope of the present disclosure.

FIGS. 17A-17D are cross-sectional views of the wafer 101, in accordance with some embodiments. The cross-sectional views of FIGS. 17A-17C correspond to the cut lines 5A-5C, though at a further stage of processing. The cross-sectional view of FIG. 17D is taken along cut lines 17D of FIG. 17A.

In FIGS. 17A-17D, an interlevel dielectric layer 179 has been formed over the gate metal 172, the gate spacers 130, and other exposed structures of the top side or front side of the wafer 101. The interlevel dielectric layer 179 one includes one or more of SiO, SiN, SiON, SiOCN, SiCN, FSG, or other suitable dielectric materials. The interlevel dielectric layer 179 can be formed by CVD, PVD, or other suitable deposition processes.

In FIGS. 17A-17D, a photolithography and corresponding etching process have been performed to etch portions of the dielectric layers 179, 160, and 158 to expose the source/drain regions 150b of the transistor 174b of the CFET 103. A silicide 180b has been formed on the exposed top surfaces of the source/drain regions 150b. The silicide 180b can include titanium silicide, nickel silicide, or other types of silicide. After formation of the silicide 180b, source/drain contacts 182b are formed in contact with the silicide 180b. The source/drain contacts 182b can include one or more of W, Ta, Ti, Ru, Co, TiN, TaN, WN, or other suitable conductive materials. A CMP process has been performed to remove excess material of the source/drain contacts 182b. The source/drain contacts 182b enable voltages to be applied to the source/drain regions 150b.

Though not shown in FIGS. 17A-17D, after formation of the source/drain contacts 182b, a stack of dielectric layers is formed over the CFET 103. A plurality of metal lines and conductive vias are formed in the stack of dielectric layers to enable the provision of signals to and from the CFETs 103.

In FIGS. 17A-17D, after formation of the interconnect structures above the CFET 103, the wafer 101 is flipped so that backside processing can be performed. In the backside processing, the semiconductor substrate 102a is removed. This can be accomplished by performing an etching process that selectively etches the material of the semiconductor substrate 102, a with respect to the material of the dielectric isolation structures 120. A dielectric layer 178 is then formed in place of the semiconductor substrate 102a. The dielectric layer 178 one includes one or more of SiO, SiN, SiON, SiOCN, SiCN, FSG, or other suitable dielectric materials. The interlevel dielectric layer 178 can be formed by CVD, PVD, or other suitable deposition processes.

In FIGS. 17A-17D, a photolithography and corresponding etching process have been performed to etch portions of the dielectric layer 178 to expose the source/drain regions 150a of the transistor 174a of the CFET 103 from the backside. A silicide 180a has been formed on the exposed surfaces of the source/drain regions 150a. The silicide 180a can include titanium silicide, nickel silicide, or other types of silicide. After formation of the silicide 180a, source/drain contacts 182a are formed in contact with the silicide 180a. The source/drain contacts 182a can include one or more of W, Ta, Ti, Ru, Co, TiN, TaN, WN, or other suitable conductive materials. A CMP process has been performed to remove excess material of the source/drain contacts 182a. The source/drain contacts 182a enable voltages to be applied to the source/drain regions 150a.

Though not shown in FIGS. 17A-17D, after formation of the source/drain contacts 182a, a stack of dielectric layers is formed on the backside of the CFET 103. A plurality of metal lines and conductive vias are formed in the stack of dielectric layers to enable the provision of signals to and from the CFETs 103.

The cross-sectional view of FIG. 17D illustrates that the gate metal 172 has an outer gate length with a dimension D1. The outer gate length corresponds to the width of the gate metal 172 in the X direction in the locations previously occupied by the sacrificial gate layer 126. Accordingly, the gate metal 172 has a dimension D1 in the gate trench 164 above the channels 109 and laterally spaced apart from the channels 109 in the Y direction.

The cross-sectional view of FIG. 17D illustrates that the gate metal 172 has an inner gate length with a dimension D2. The inner gate length corresponds to the width of the gate metal 172. In the X direction in the locations previously occupied by the sacrificial semiconductor nanostructures 111a/b. As can be seen in FIG. 17D, D2 is smaller than D1. In some embodiments, D1 is between 8 nm and 20 nm. In some embodiments, D2 is between 5 nm and 18 nm. In some embodiments, the difference between D1 and D2 is between one nanometer and 10 nm. Other dimensions can be utilized without departing from the scope of the present disclosure.

FIGS. 1A-17D illustrate a single CFET 103, in accordance with some embodiments. In practice, a plurality of CFETs 103 are formed in each fin 116. Accordingly, the wafer 101 includes a plurality of CFETs. The wafer 101 will eventually be diced into a plurality of integrated circuits. Each integrated circuit includes a plurality of CFETs 103.

In some embodiment, the shorter inner gate length can increase driving current and reduce channel capacitance (induced by metal gate and channel). This results in improved switching speeds and overall device performance. By scaling down the inner gate length only while keeping the outer gate length unchanged, the process window can be improved, so that the challenges associated with the gate replacement process, such as Vt tuning via work function material and the use of multiple metal gates, are minimized. That is, since the outer gates are larger than the inner gates, the spaces between channels (where inner gates to be formed) can be filled well before the gate fill material merging at the upper portions (where outer gates to be formed), so as to avoid generating seams or voids in the inner gates.

In some embodiments, the top channel 109b has an asymmetric gate length because its topside is in contact with the outer gate (longer gate length D2), while its bottom-side is in contact with the inner gate (shorter gate length D1).

Furthermore, by providing different wafer crystal lattice orientations or materials for NFETs and PFETs, the mobility can be kept or the mobility degradation induced by the thin channel height can be reduced.

FIGS. 1A-17D illustrate a single CFET 103, in accordance with some embodiments. In practice, a plurality of CFETs 103 are formed in each fin 116. Accordingly, the wafer 101 includes a plurality of CFETs. The wafer 101 will eventually be diced into a plurality of integrated circuits. Each integrated circuit includes a plurality of CFETs 103.

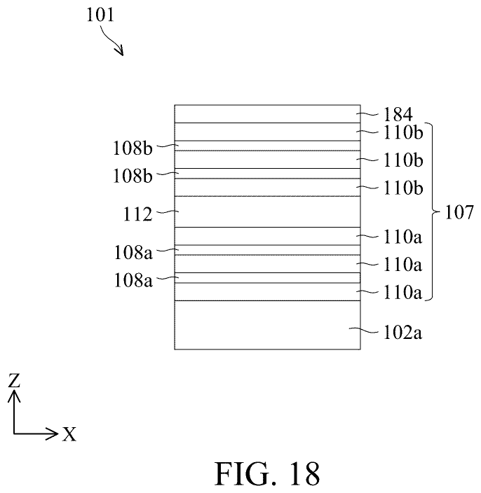

FIG. 18-X are cross-sectional views of a process for forming CFETs 103 is a wafer 101, in accordance with some embodiments. At the stage of processing shown in FIG. 18, the compounds wafer 101 has been formed substantially as described in relation to FIGS. 1A-3B. The wafers 100a and 100b have been brought together and the thermal annealing processes been performed to bond the wafers 100a and 100b into the compounds wafer 101.

In FIG. 18, the semiconductor substrate 102B has been removed. The semiconductor substrate 102B can be removed via an etching process, or a CMP process. A hard mask layer 184 has been formed on the top sacrificial semiconductor layer 110 B. The hard mask layer 184 includes one or more of SiO2, SiN, SiON, SiCN, SiOCN, SiOC, Al2O3, HfO2, ZrO2, SiC, or other suitable dielectric materials. The hard mask layer 184 has a thickness between 2 nm and 30 nm, though other thicknesses can be utilized without departing from the scope of the present disclosure. The hard mask layer 184 can be formed by CVD, ALD, PVD, or other suitable deposition processes.

The hard mask layer 184 corresponds to a gate protection hard mask layer, as will be set forth in more detail below. In some embodiments, in the final structure the gate protection hard mask is little or no loss. In some embodiments, the gate protection hard mask can be removed entirely by CMP near the end of processing.

FIGS. 18-26C are cross-sectional views a wafer 101 at intermediate stages of a process for forming CFETs 103, in accordance with some embodiments. At the stage of processing shown in FIG. 18, the compound wafer 101 has been formed substantially as described in relation to FIGS. 1A-3B. The wafers 100a and 100b have been brought together and the thermal annealing processes been performed to bond the wafers 100a and 100b into the compounds wafer 101.

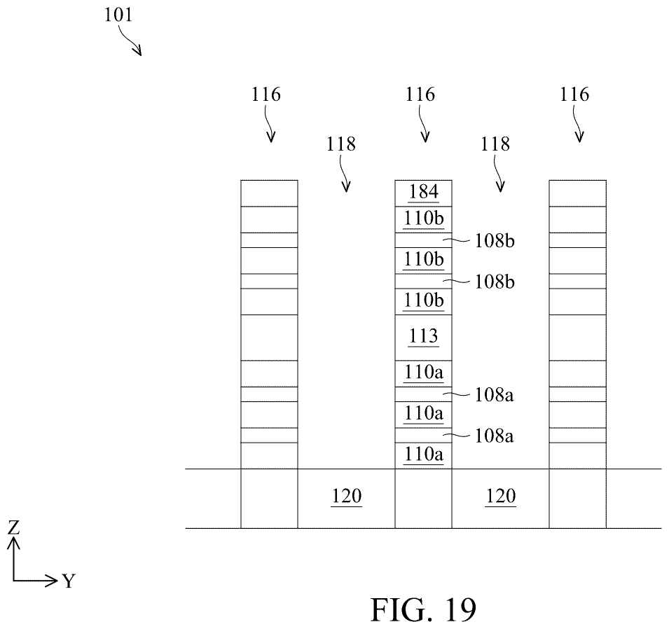

In FIG. 19, a plurality of fins 116 have been formed from the stack 107, in accordance with some embodiments. The fins 116 are formed as described in relation to FIGS. 4A and 4B, except that each fin 116 includes the hard mask layer 184 and there is a sacrificial semiconductor layer 110b on the top semiconductor layer 110a. Dielectric isolation structures have been formed 120 have been formed as described previously.

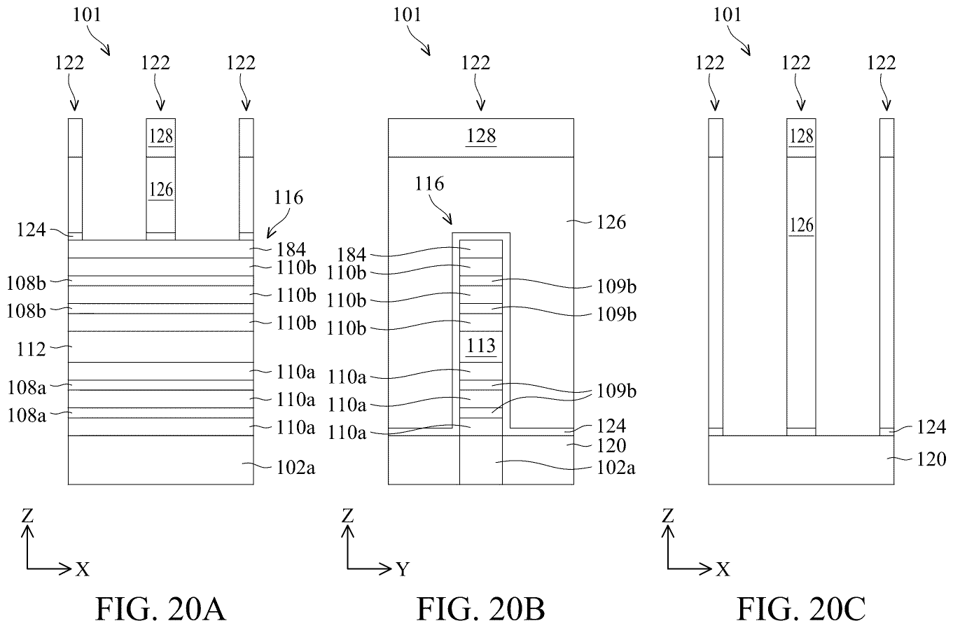

FIGS. 20A-20C are cross-sectional views of the wafer 101, in accordance with some embodiments. In FIGS. 20A-20C, a plurality of sacrificial gate structures 122 have been formed, in accordance with some embodiments. The sacrificial gate structures 122 are formed substantially as described in relation to FIGS. 5A-5D, except that the sacrificial gate structures 126 are formed on the hard mask layer 184.

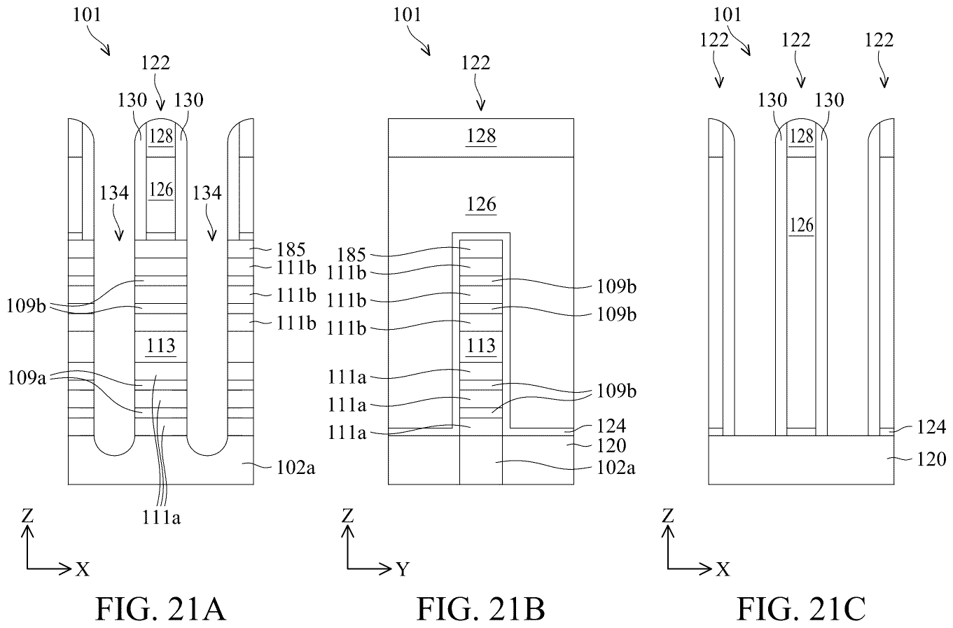

FIGS. 21A-21C are cross-sectional views of the wafer 101, in accordance with some embodiments. In FIGS. 21A-21C, source/drain trenches 134 have been formed as described in relation to FIGS. 6A-6C. Formation of the source/drain trenches 134 results in the formation of channels 109a/b, sacrificial semiconductor nanostructures 111a/b, the middle isolation structure 113, as described in relation to FIGS. 6A-6C. Formation of the source/drain trenches 134 also results in formation of hard mask nanostructures 185 from the hard mask layer 184.

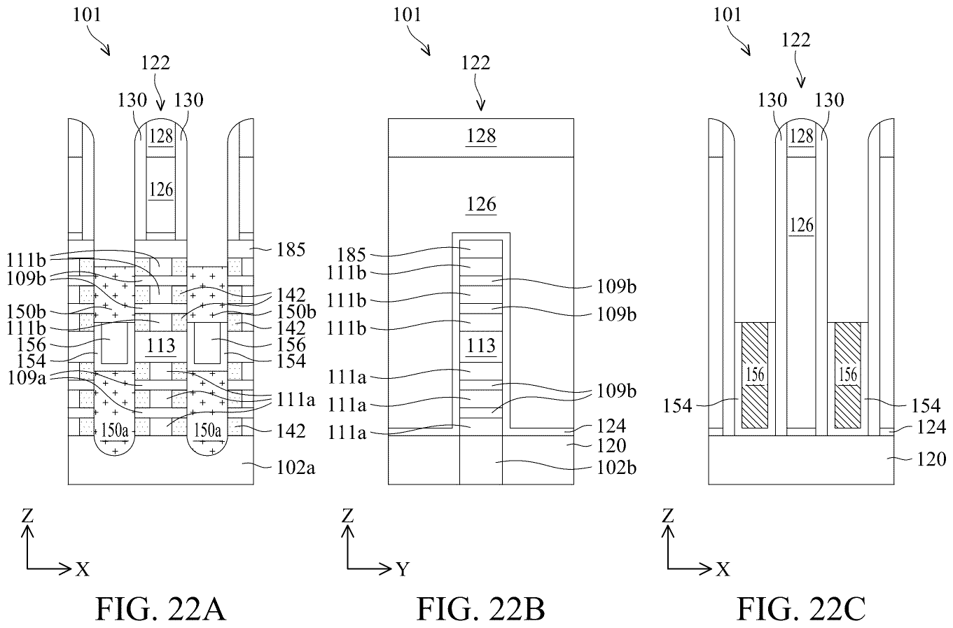

FIGS. 22A-22C are cross-sectional views of the wafer 101, in accordance with some embodiments. In FIGS. 22A-22C, inner spacers 142, source/drain regions 150a/b, CESL 154, and dielectric layer 156 have been formed substantially as described in relation to FIGS. 7A-13C, except that the hard mask nanostructure 185 is present.

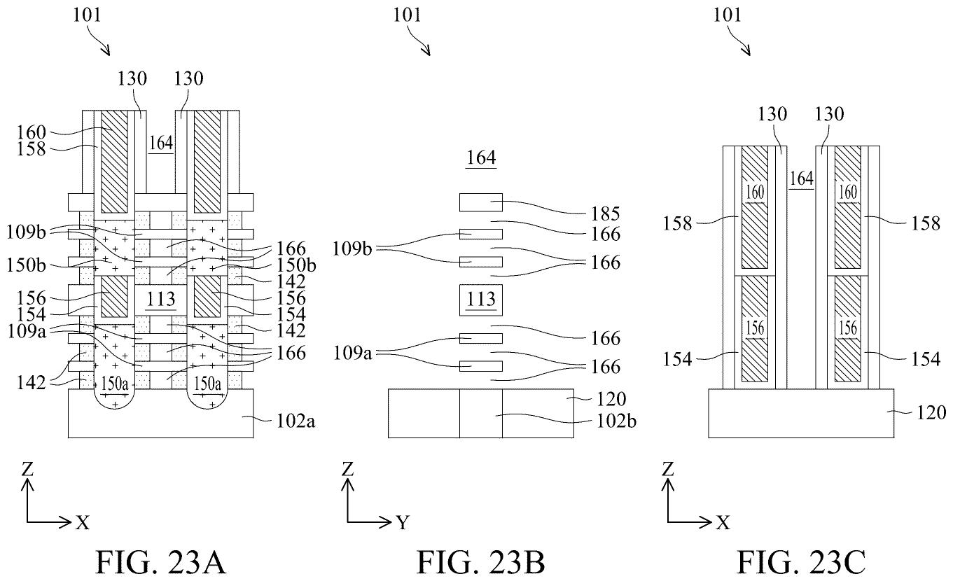

FIGS. 23A-23C are cross-sectional views of the wafer 101, in accordance with some embodiments. In FIGS. 23A-23C, the CESL 158, the interlevel dielectric layer 160, the gate trench 164 and the gaps 166 have been formed, substantially as described in relation to FIGS. 14A-15C, except that the hard mask nanostructure 185 is present.

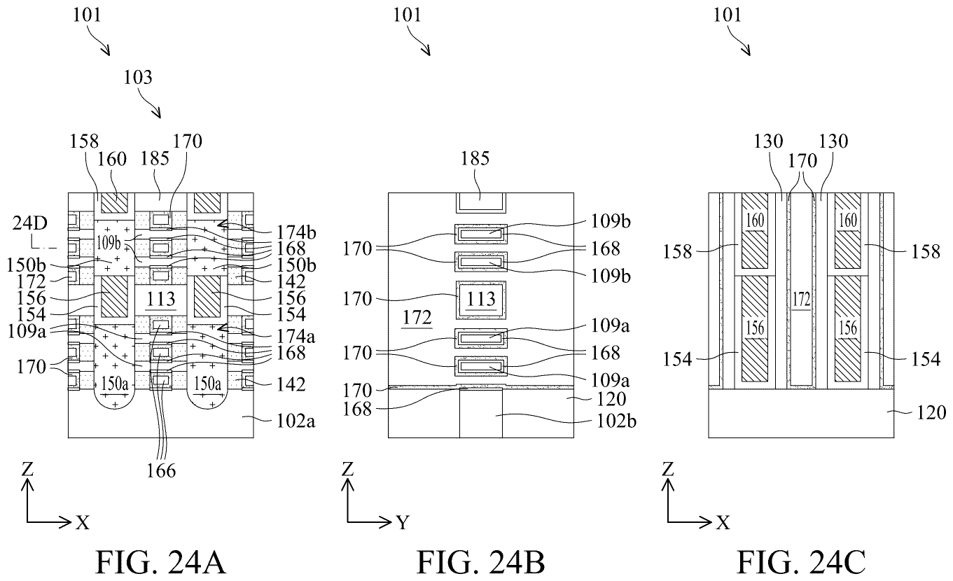

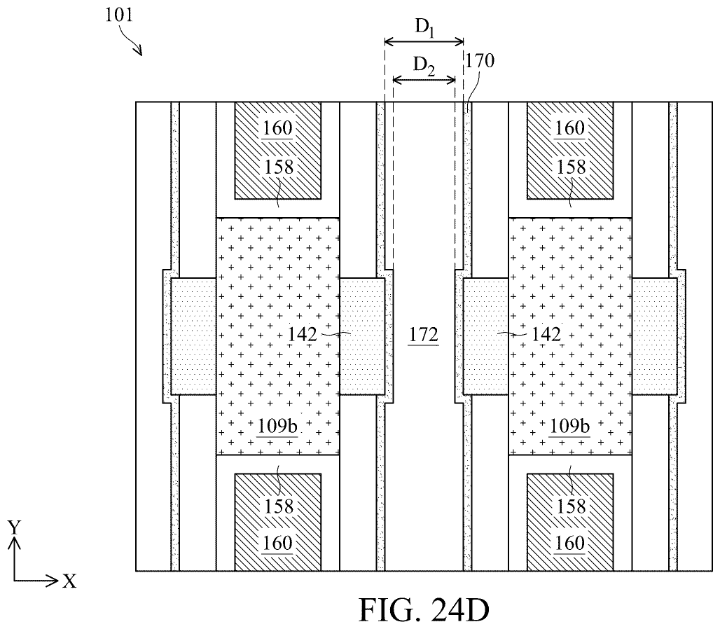

FIGS. 24A-24D are cross-sectional views of the wafer 101, in accordance with some embodiments. In FIGS. 24A-24D, the sacrificial semiconductor nanostructures 111a/b have been removed, the interfacial gate dielectric layer 168 has been formed, the high-K gate dielectric layer 170 has been formed, and the gate metal 172 has been formed substantially as described in relation to FIGS. 16A-16D. A CMP process has been performed to make the top surface of the gate metal 172 coplanar with the top surface of the hard mask nanostructure 185.

The cross-sectional view of FIG. 24D illustrates the short gate length D2 and the longer gate length D1, as described previously in relation to FIG. 17D.

In some embodiments, the hard mask nanostructure 185 has substantially the same dimensions in the X and Y directions as the channels 109a/b.

In 24A-24D, the gate length above the top channel 109b is the same as below the top channel 109b. In other words, the gate metal 172 has the same gate length D2 above the top channel 109b as below the top channel 109b.

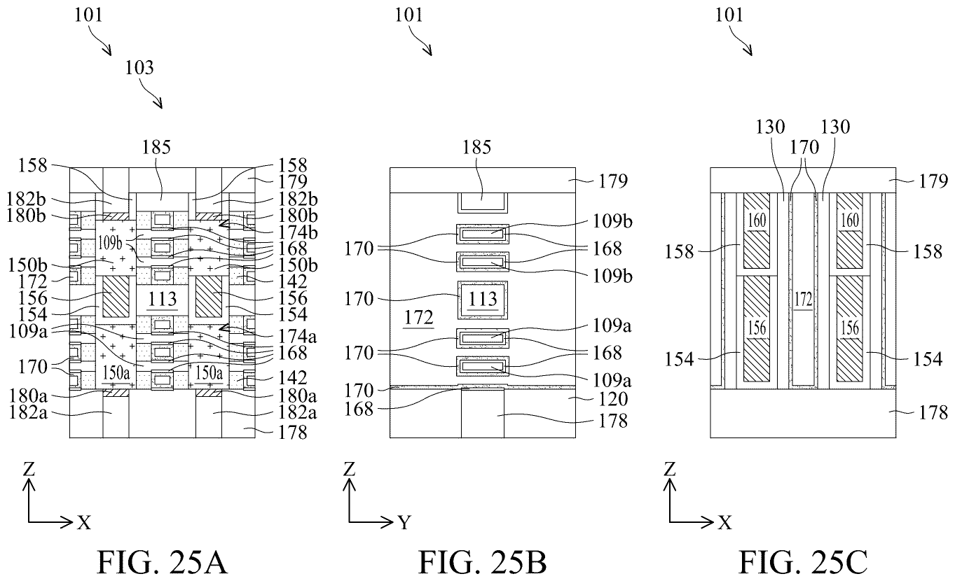

FIGS. 25A-25C are cross-sectional views of the wafer 101, in accordance with some embodiments. In FIGS. 25A-25C, the dielectric layers 178 and 179, the silicide 180a/b, and the source/drain contacts 182a/b have been formed, substantially as described in relation to FIGS. 17A-17C.

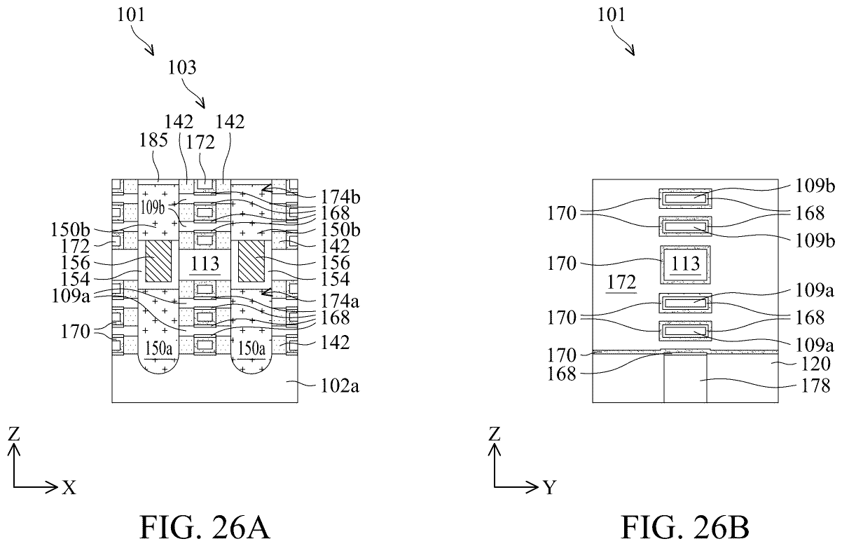

FIGS. 26A and 26B are cross-sectional views of a wafer 101, in accordance with some embodiments. The wafer 101 of FIGS. 26A and 26B is substantially similar to the wafer 101 of FIGS. 24A-C, except that a CMP processes been performed to entirely remove the hard mask nanostructure 185, in accordance with some embodiments. The top surface of the gate metal 172 is coplanar with the top surfaces of the highest inner spacers 142.

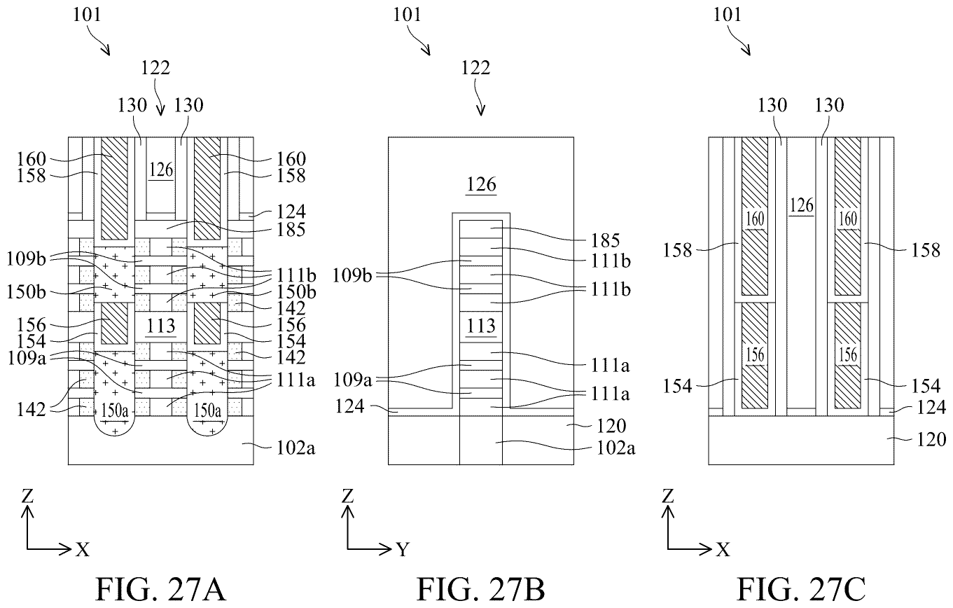

FIGS. 27A-29D are cross-sectional views a wafer 101 at intermediate stages of a process for forming CFETs 103, in accordance with some embodiments.

FIGS. 27A-27C are cross-sectional views of the wafer 101 at a stage of processing, corresponding to the stage of processing shown in FIGS. 22A-22C, with the addition that the dielectric layers 158 and 160 have been formed. At the stage of processing shown in FIG. 27A-C, the compounds wafer 101 has been formed substantially as described in relation to FIGS. 1A-3B. The wafers 100a and 100b have been brought together and the thermal annealing processes been performed to bond the wafers 100a and 100b into the compounds wafer 101.

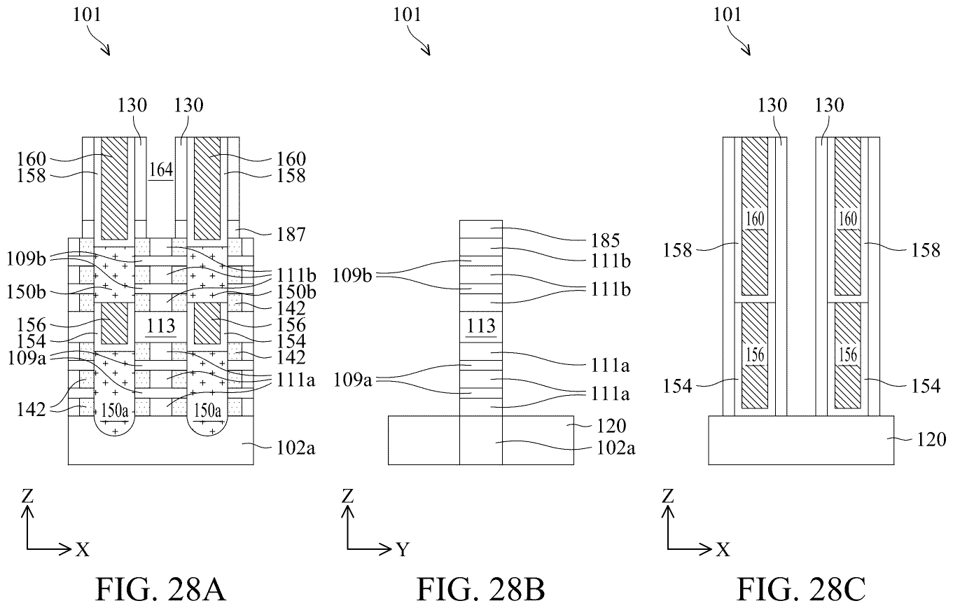

In FIGS. 28A-28C, an etching process has been performed, in accordance with some embodiments. The etching process removes a central portion of the hard mask nanostructure 185 not covered by the gate spacer layer 130, in accordance with some embodiments. The etching process is an anisotropic etching process that etches in the downward direction and selectively etches the material of the hard mask nanostructure 185 with respect to other exposed materials. After the etching process, hard mask remnants 187 are present on top of the highest inner spacers 142. A portion of the top surface of the highest inner spacers 142 is also exposed.

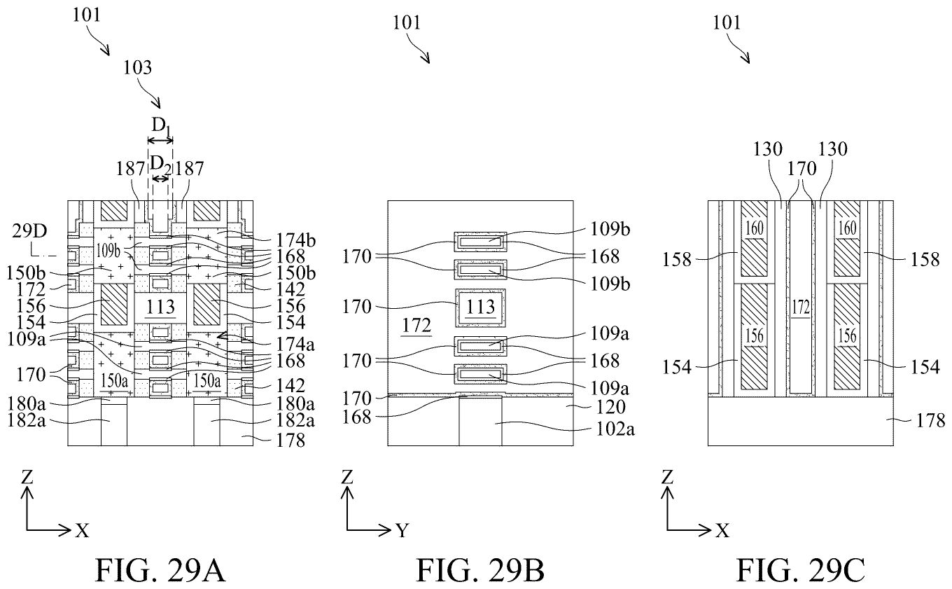

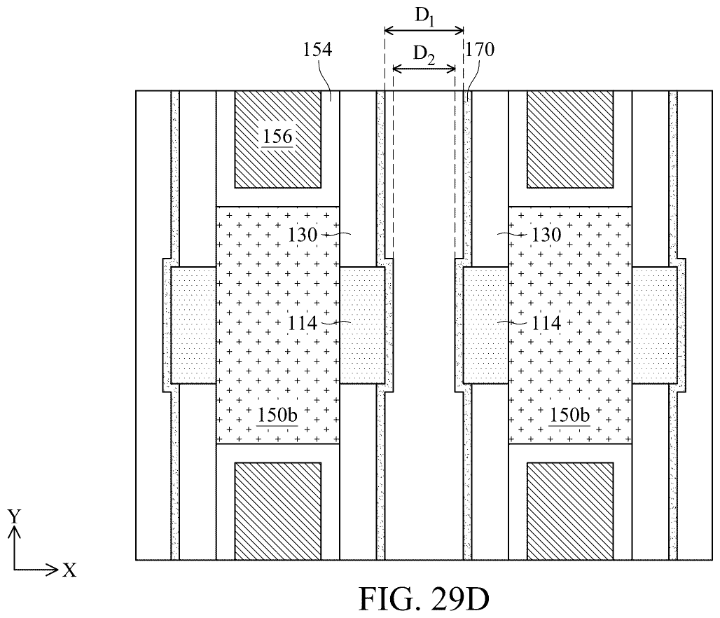

In FIGS. 29A-29D, the sacrificial semiconductor nanostructures 111a/b have been removed, the interfacial gate dielectric layer 168 has been formed, the high-K gate dielectric layer 170 has been formed, and the gate metal 172 has been formed substantially as described in relation to FIGS. 16A-16D. FIG. 29A illustrates that the T-shape of the gate metal 172 above highest channel 109b. In particularly, the upper part of the gate metal 172 includes a first portion above the highest channels 109b with the gate length dimension D2 and a second portion above the first portion with the gate length dimension D1. The hard mask remnants 187 are present on the highest inner spacers 142. A CMP process has been performed to make the top surface of the gate metal 172 coplanar with the top surface of the hard mask remnants 187.

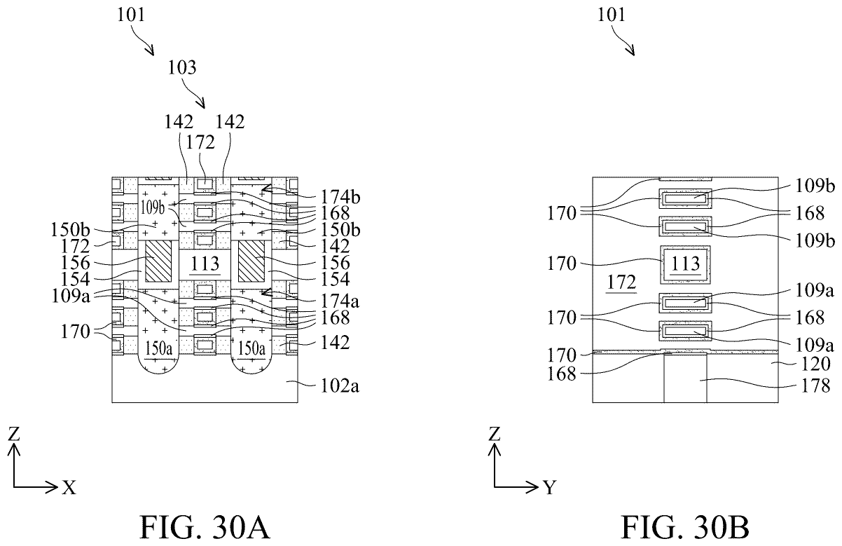

FIGS. 30A and 30B are cross-sectional views of a wafer 101, in accordance with some embodiments. The wafer 101 includes a CFET 103 substantially similar to the CFET 103 shown in relation to FIGS. 26A and 26B, except that the CMP process does not remove the top portion of the high-K gate dielectric layer 170 adjacent to the highest inner spacers 142.

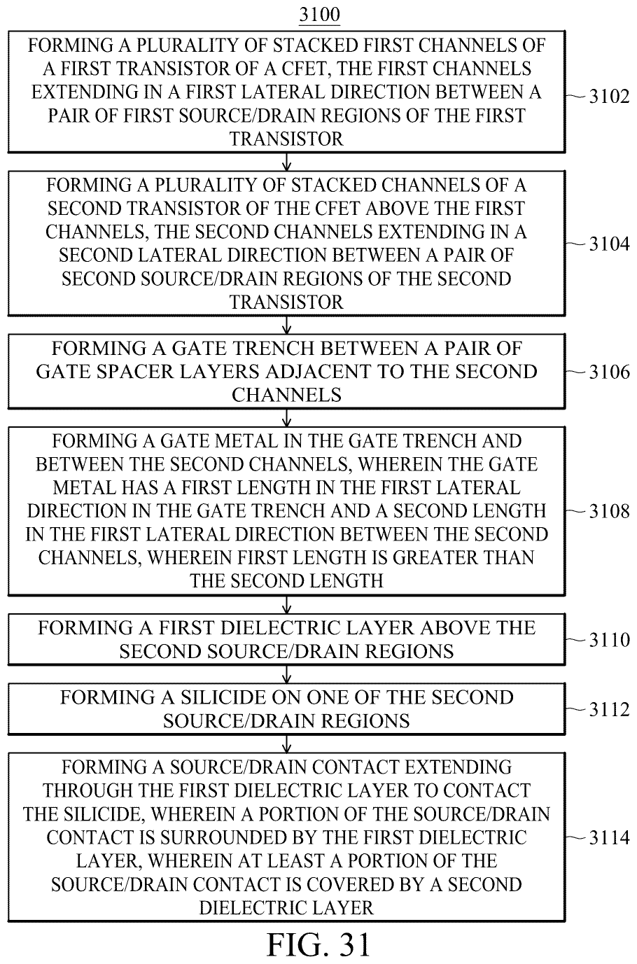

FIG. 31 is a flow diagram of a method 3100 for forming an integrated circuit, in accordance with some embodiments. The method 3100 can utilize systems, processes, components, and principles described in relation to FIGS. 1A-30B. At 3102, the method 3100 includes forming a plurality of stacked first channels of a first transistor of a CFET, the first channels extending in a first lateral direction between a pair of first source/drain regions of the first transistor. One example of a CFET is the CFET 103 of FIG. 17A. One example of a first transistor is the transistor 174a of FIG. 17A. One example of first channels are the channels 109a of FIG. 17A. One example of first source/drain regions are the source/drain regions 150a of FIG. 17A. At 3104, the method 3100 includes forming a plurality of stacked channels of a second transistor of the CFET above the first channels, the second channels extending in a second lateral direction between a pair of second source/drain regions of the second transistor. One example of a second transistor is the transistor 174b of FIG. 17A. One example of second channels are the channels 109b of FIG. 17A. One example of second source/drain regions are the second source/drain regions 150b of FIG. 17A. At 3106, the method 3100 includes forming a gate trench between a pair of gate spacer layers adjacent to the second channels. One example of a gate trench is the gate trench 164 of FIG. 15A. One example of gate spacer layers are the gate spacer layers 130 of FIG. 15A. At 3108, the method 3100 includes forming a gate metal in the gate trench and between the second channels, wherein the gate metal has a first length in the first lateral direction in the gate trench and a second length in the first lateral direction between the second channels, wherein first length is greater than the second length. One example of a gate metal is the gate metal 172 of FIG. 17A. At 3110, the method 3100 includes forming a first dielectric layer over the second source/drain regions. One example of a first dielectric layer is the dielectric layer 179. At 3112, the method 3100 includes forming a silicide on one of the second source/drain regions. One example of a silicide is the silicide 180b of FIG. 17A. At 3114, the method 3100 includes forming a source/drain contact extending through the first dielectric layer to contact the silicide, wherein the source/drain contact is surrounded by the first dielectric layer, wherein the source/drain contact is spaced apart from the first dielectric layer by a second dielectric layer having a higher dielectric constant than the first dielectric layer. One example of a second dielectric layer is the dielectric layer 158 of FIG. 17A. One example of a source/drain contact is the source/drain contact 182b of FIG. 17A.

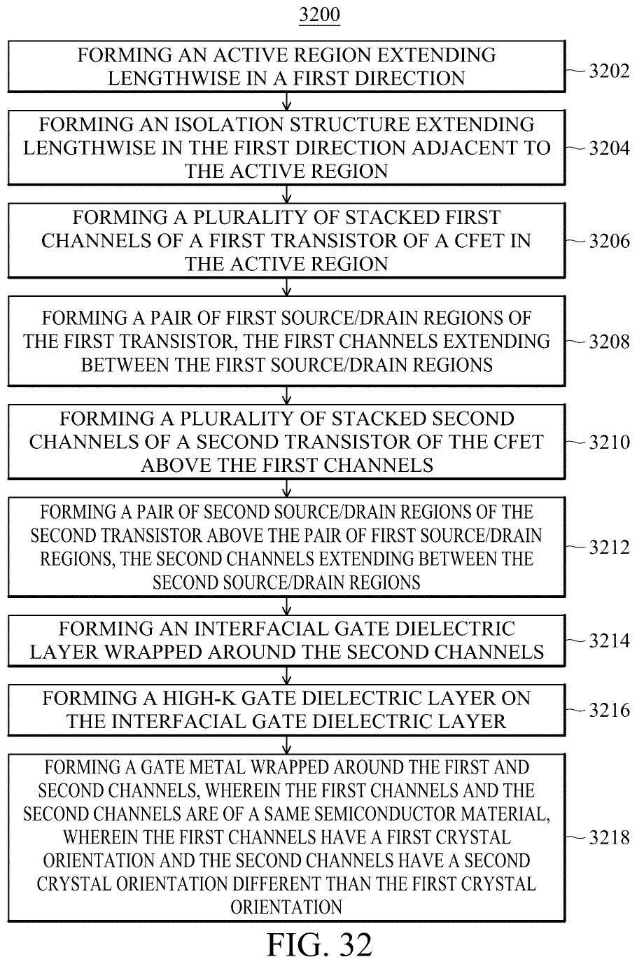

FIG. 32 is a flow diagram of a method 3200 for forming an integrated circuit, in accordance with some embodiments. The method 3200 can utilize systems, processes, components, and principles described in relation to FIGS. 1A-30B. At 3202, the method 3200 includes forming an active region extending lengthwise in a first direction. One example of an active region is the active region 116 of FIG. 4C. At 3204, the method 3200 includes forming an isolation structure extending lengthwise in the first direction adjacent to the active region. One example of an isolation structure is the isolation structure 120 of FIG. 4C. At 3206, the method 3200 includes forming a plurality of stacked first channels of a first transistor of a CFET in the active region. One example of first channels is the channels 109a of FIG. 17A. One example of a CFET is the CFET 103 of FIG. 17A. One example of a first transistor is the transistor 174a of FIG. 17A. At 3208, the method 3200 includes forming a pair of first source/drain regions of the first transistor, the first channels extending between the first source/drain regions. One example first source/drain regions are the source/drain regions 150a of FIG. 17A. At 3210, the method 3200 includes forming a plurality of stacked second channels of a second transistor of the CFET above the first channels. One example of a second transistor is the transistor 174b of FIG. 17A. One example of second channels are the second channels 109b of FIG. 17A. At 3212, the method 3200 includes forming a pair of second source/drain regions of the second transistor above the pair of first source/drain regions, the second channels extending between the second source/drain regions. One example of second source/drain regions is the source/drain regions 150b of FIG. 17A. At 3214, the method 3200 includes forming an interfacial gate dielectric layer wrapped around the second channels. One example of an interfacial gate dielectric layer is the interfacial gate dielectric layer 168 of FIG. 17A. At 3216, the method 3200 includes forming a high-K gate dielectric layer on the interfacial gate dielectric layer. One example of a high-K gate dielectric layer is the high-K gate dielectric layer 170 of FIG. 17A. At 3218, the method 3200 includes forming a gate metal wrapped around the first and second channels, wherein the first channels and the second channels are of a same semiconductor material, wherein the first channels have a first crystal orientation and the second channels have a second crystal orientation different than the first crystal orientation. One example of a gate metal is the gate metal 172 of FIG. 17A.

Embodiments of the present disclosure provide an integrated circuit including a CFET with improved electrical characteristics. The CFET includes an NFET transistor and a PFET transistor stacked together. Embodiments of the present disclosure provide a CFET in which the inner gate length is shorter than the outer gate length and in which the channels have reduced vertical thicknesses. Embodiments of the present disclosure also provide a CFET having different crystal orientations for the channels of the PFET and NFET transistors.

The reduced inner gate length helps reduce the undesirable short channel effect. The different crystal orientations for the PFET channels and the NFET channels help ensure that both the NFET charge carriers and the PFET charge carriers have strong mobility. This further enables the reduced vertical thickness of the channels, resulting in smaller stacking heights. The result is integrated circuits with dense arrays of properly functioning CFETs with good conduction and switching characteristics. This leads to better performing devices and higher wafer yields.

In some embodiments, a method includes forming a plurality of stacked first channels of a first transistor of a CFET. The first channels extend in a first lateral direction between a pair of first source/drain regions of the first transistor. The method includes forming a plurality of stacked channels of a second transistor of the CFET above the first channels. The second channels extend in a second lateral direction between a pair of second source/drain regions of the second transistor. The method includes forming a gate trench between a pair of gate spacer layers adjacent to the second channels and forming a gate metal in the gate trench and between the second channels. The gate metal has a first length in the first lateral direction in the gate trench and a second length in the first lateral direction between the second channels, wherein first length is greater than the second length. The method includes forming a first dielectric layer above the second source/drain regions, forming a silicide on one of the second source/drain regions, and forming a source/drain contact extending through the first dielectric layer to contact the silicide. A portion of the source/drain contact is surrounded by the first dielectric layer. A portion of the source/drain contact is covered by a second dielectric layer.

In some embodiments, a method includes forming an active region extending lengthwise in a first direction, forming an isolation structure extending lengthwise in the first direction adjacent to the active region, and forming a plurality of stacked first channels of a first transistor of a CFET in the active region. The method includes forming a pair of first source/drain regions of the first transistor. The first channels extend between the first source/drain regions. The method includes forming a plurality of stacked second channels of a second transistor of the CFET above the first channels and forming a pair of second source/drain regions of the second transistor above the pair of first source/drain regions. The second channels extend between the second source/drain regions. The method includes forming an interfacial gate dielectric layer wrapped around the second channels, forming a high-K gate dielectric layer on the interfacial gate dielectric layer, and forming a gate metal wrapped around the first and second channels. The first channels and the second channels are of a same semiconductor material. The first channels have a first crystal orientation and the second channels have a second crystal orientation different than the first crystal orientation.

In some embodiments, a device includes a substrate, an active region disposed over the substrate and extending lengthwise along a first lateral direction, and an isolation structure disposed over the substrate alongside the active region. The device includes a CFET in the active region including a first transistor including a pair of first source/drain regions and a plurality of stacked first channels extending in the first lateral direction between the pair of first source/drain regions such that sidewalls of the first channels interface first source/drain regions. The CFET includes a second transistor above the first transistor and including a pair of second source/drain regions and a plurality of stacked second channels extending in the first lateral direction between the pair of second source/drain regions. The device includes a pair of gate spacer layers defining a gate trench adjacent to the second channels and a gate metal in the gate trench and between the second channels. The gate metal has a first length in the first lateral direction in the gate trench and a second length in the first lateral direction between the second channels. The first length is greater than the second length.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of stacked first channels of a first transistor of a CFET, the first channels extending in a first lateral direction between a pair of first source/drain regions of the first transistor;
forming a plurality of stacked second channels of a second transistor of the CFET above the first channels, the second channels extending in a second lateral direction between a pair of second source/drain regions of the second transistor;
forming a gate trench between a pair of gate spacer layers adjacent to the second channels;
forming a gate metal in the gate trench and between the second channels, wherein the gate metal has a first length in the first lateral direction in the gate trench and a second length in the first lateral direction between the second channels, wherein first length is greater than the second length;
forming a first dielectric layer above the second source/drain regions;
forming a silicide on one of the second source/drain regions; and
forming a source/drain contact extending through the first dielectric layer to contact the silicide, wherein a portion of the source/drain contact is surrounded by the first dielectric layer, wherein at least a portion of the source/drain contact is covered by a second dielectric layer.

2. The method of claim 1, further comprising:
forming the gate spacer layers above the second channels;
forming recesses by recessing, in the first direction, a plurality of sacrificial semiconductor nanostructures between the second channels;
forming inner spacers in the recesses;
removing the sacrificial semiconductor nanostructures; and
forming the gate metal in place of the sacrificial semiconductor nanostructures, wherein the second gate length is based on a distance in the first lateral direction between adjacent inner spacers.

3. The method of claim 2, wherein after recessing the sacrificial semiconductor nanostructures a width of the sacrificial semiconductor nanostructures in the first lateral direction is less than a distance between the gate spacer layers.

4. The method of claim 1, wherein the gate metal has the first length on a top surface of a highest second channel of the plurality of second channels, wherein the gate metal has the second length on the bottom surface of the highest second channel.

5. The method of claim 1, further comprising forming a hardmask nanostructure over the second channels, wherein forming the gate metal includes forming the gate metal between the hard mask nanostructure and a highest second channel of the plurality of second channels.

6. The method of claim 5, wherein the gate metal has the first length on a top surface of the hard mask nanostructure, wherein the gate metal has the second length between the hard mask nanostructure and the highest second channel of the plurality of second channels.

7. The method of claim 5, further comprising:
removing a central portion of the hard mask nanostructure; and
forming the gate metal between adjacent remnants of the hard mask nanostructure above the highest second channel of the plurality of second channels.

8. The method of claim 7, wherein the gate metal has a T-shape above the highest second channel.

9. The method of claim 8, wherein the gate metal has the first length between the remnants of the hard mask nanostructure, wherein the gate metal has the first length above the remnants of the hard mask nanostructure.

10. The method of claim 7, wherein a top surface of the gate metal is coplanar with top surfaces of the remnants of the hard mask structure.

11. The method of claim 1, wherein the first channels and the second channels are of a same semiconductor material, wherein the first channels have a first crystal orientation and the second channels have a second crystal orientation different than the first crystal orientation.

12. A method, comprising:
forming an active region extending lengthwise in a first direction;
forming an isolation structure extending lengthwise in the first direction adjacent to the active region;
forming a plurality of stacked first channels of a first transistor of a CFET in the active region;
forming a pair of first source/drain regions of the first transistor, the first channels extending between the first source/drain regions;
forming a plurality of stacked second channels of a second transistor of the CFET above the first channels;
forming a pair of second source/drain regions of the second transistor above the pair of first source/drain regions, the second channels extending between the second source/drain regions;
forming an interfacial gate dielectric layer wrapped around the second channels;
forming a high-K gate dielectric layer on the interfacial gate dielectric layer;
forming a gate metal wrapped around the first and second channels, wherein the first channels and the second channels are of a same semiconductor material, wherein the first channels have a first crystal orientation and the second channels have a second crystal orientation different than the first crystal orientation.

13. The method of claim 12, further comprising:
forming a plurality of first semiconductor layers of the first material via an epitaxial growth process from a first semiconductor substrate of a first wafer having the first crystal orientation;
forming a plurality of first semiconductor layers of the first material via an epitaxial growth process from a first semiconductor substrate of a first wafer having the first crystal orientation;
forming a compound wafer by bonding the first wafer to the second wafer;
forming the first channels from the first semiconductor layers in the active region; and
forming the second channels from the second semiconductor layers in the active region.

14. The method of claim 13, wherein:
the semiconductor material is silicon;
the first transistor is a PFET;
the first crystal orientation is 110;
the second transistor is an NFET; and
the second crystal orientation is 100.

15. The method of claim 13, wherein:
the semiconductor material is silicon;
the first transistor is an NFET;
the first crystal orientation is 100;
the second transistor is a PFET; and
the second crystal orientation is 110.

16. A device, comprising:
a substrate;
an active region disposed over the substrate and extending lengthwise along a first lateral direction;
an isolation structure disposed over the substrate alongside the active region;
a CFET in the active region including:
a first transistor including:
a pair of first source/drain regions; and
a plurality of stacked first channels extending in the first lateral direction between the pair of first source/drain regions such that sidewalls of the first channels interface first source/drain regions;
a second transistor above the first transistor including:
a pair of second source/drain regions; and
a plurality of stacked second channels extending in the first lateral direction between the pair of second source/drain regions;
a pair of gate spacer layers defining a gate trench adjacent to the second channels; and
a gate metal in the gate trench and between the second channels, wherein the gate metal has a first length in the first lateral direction in the gate trench and a second length in the first lateral direction between the second channels, wherein first length is greater than the second length.

17. The device of claim 16, wherein the first channels and the second channels are of a same semiconductor material, wherein the first channels have a first crystal orientation and the second channels have a second crystal orientation different than the first crystal orientation.

18. The device of claim 16, wherein the gate metal has the first length on a top surface of a highest second channel of the plurality of second channels, wherein the gate metal has the second length on a bottom surface of the highest second channel.

19. The device of claim 16, further comprising a hardmask nanostructure over the second channels, wherein the gate metal is between the hard mask nanostructure and a highest second channel of the plurality of second channels, wherein the gate metal has the first length on a top surface of the hard mask nanostructure, wherein the gate metal has the second length between the hard mask nanostructure and the highest second channel of the plurality of second channels.

20. The device of claim 16, further comprising:
a pair of inner spacers on a highest second channel; and
a respective hard mask remnant on each inner spacer below a respective gate spacer layer, wherein the gate metal is between the hard mask remnants and has a T-shape above the highest second channel, wherein the gate metal has the second length between the hard mask remnants, wherein the gate metal has the first length above the hard mask remnants.
